(19) United States
(12) Patent Application Publication
(10) Pub. No.: US 2017/0345475 A1
(43) Pub. Date: Nov. 30, 2017

(54) RESISTIVE-TYPE MEMORY DEVICES AND INTEGRATED CIRCUITS INCLUDING THE SAME

(71) Applicants: Choong-Jae LEE, Hwaseong-si (KR); Gwan-Hyeob KOH, Seoul (KR); Bo-Young SEO, Suwon-si (KR); Yong-Kyu LEE, Gwacheon-si (KR)

(72) Inventors: Choong-Jae LEE, Hwaseong-si (KR); Gwan-Hyeob KOH, Seoul (KR); Bo-Young SEO, Suwon-si (KR); Yong-Kyu LEE, Gwacheon-si (KR)

(21) Appl. No.: 15/402,231

(22) Filed: Jan. 9, 2017

(30) Foreign Application Priority Data
May 25, 2016 (KR) 10-2016-0064043

(51) Int. Cl. G11C 11/16

(52) U.S. Cl. CPC G11C 11/161; G11C 11/1673; G11C 11/1655; G11C 11/1657

(57) ABSTRACT

A resistive-type memory device is disclosed. The resistive-type memory device includes a memory cell array and a control logic circuit. The control logic circuit accesses the memory cell array in response to a command and an address provided from an outside. The memory cell array includes at least a first group of resistive-type memory cells and a second group of resistive-type memory cells. Each of the first group of resistive-type memory cells has a first feature size and each of the second group of resistive-type memory cells has a second feature size that is different from the first feature size.

### CROSS-REFERENCE TO RELATED APPLICATION(S)

This U.S. non-provisional application claims the benefit of priority under 35 U.S.C. §119 to Korean Patent Application No. 10-2016-0064043, filed on May 25, 2016, in the Korean Intellectual Property Office, the content of which is incorporated herein in its entirety by reference.

### BACKGROUND

### 1. Technical Field

Exemplary embodiments relate to memory devices, and more particularly to resistive-type memory devices and integrated circuits including the resistive-type memory devices.

### 2. Discussion of the Related Art

Semiconductor memory devices can be roughly divided into two categories according to whether they retain stored data when disconnected from power. The two categories include volatile memory devices, which lose stored data when disconnected from power, and nonvolatile memory devices, which retain stored data when disconnected from power. Examples of volatile memory devices include static random access memory (SRAM) and dynamic random access memory (DRAM). Examples of nonvolatile memory devices include phase-change random access memory (PRAM), resistive random access memory (RRAM), magnetic random access memory (MRAM), and ferroelectric random access memory (FRAM).

### SUMMARY

Some exemplary embodiments may provide a resistive-type memory device capable of reducing power consumption and increasing data retention time.

Some exemplary embodiments may provide an integrated circuit including the resistive-type memory device capable of reducing power consumption and increasing data retention time.

According to exemplary embodiments, a resistive-type memory device includes a memory cell array and a control logic circuit. The control logic circuit accesses the memory cell array in response to a command and an address provided from an external device. The memory cell array includes at least a first group of resistive-type memory cells and a second group of resistive-type memory cells. Each of the first group of resistive-type memory cells has a first feature size and each of the second group of resistive-type memory cells has a second feature size that is different from the first feature size.

According to exemplary embodiments, an integrated circuit includes an input/output circuit, a first resistive-type memory, a second resistive-type memory and a control circuit. The input/output circuit receives input data and provides output data. The first resistive-type memory includes a plurality of first resistive-type memory cells. The second resistive-type memory includes a plurality of second resistive-type memory cells. The control circuit controls the input/output circuit to store the input data in at least a portion of the first resistive-type memory and the second resistive-type memory IP. Each of the first resistive-type memory cells has a first feature size and each of the second resistive-type memory cells has a second feature size that is different from the first feature size. The first feature size may be less than the second feature size.

Accordingly, a resistive-type memory device includes first resistive-type memory cells and second resistive-type memory cells, each of the first resistive-type memory cells has a first feature size and each of the second resistive-type memory cells has a second feature size that is greater than the first feature size. Therefore, the resistive-type memory device may provide both a low-power characteristic and a high data-retention characteristic.

According to exemplary embodiments, a memory device may include a first group of resistive-type memory cells, a second group of resistive-type memory cells, and a controller that may be coupled to the first group of resistive-type memory cells and the second group of resistive-type memory cells. Each memory cell of the first group of resistive-type memory cells may include a first feature size, and each memory cell of the second group of resistive-type memory cells may include a second feature size that is different than the first feature size. The controller may determine if an attribute of data received to be stored in the memory device indicates that the received data is to be stored in the first group of resistive-type memory cells or the second group of resistive-type memory cells.

According to exemplary embodiments, a memory device may include a memory cell array and a controller that may be coupled to the memory cell array. The memory cell array may include a plurality of bank arrays in which each bank array may include a first group of resistive-type memory cells and a second group of resistive-type memory cells. Each memory cell of the first group of resistive-type memory cells may include a first feature size, and each memory cell of the second group of resistive-type memory cells may include a second feature size that is different than the first feature size. The controller may determine if an attribute of data received to be stored in the memory device indicates that the received data is to be stored in the first group of resistive-type memory cells or the second group of resistive-type memory cells.

According to exemplary embodiments, a method of storing data in a memory device may include: receiving data to be stored in the memory device; storing the received data in a first group of resistive-type memory cells if an attribute of the received data indicates that the received data has a low data-retention characteristic, each memory cell of the first group of resistive-type memory cells comprising a first feature size; and storing the received data in a second group of resistive-type memory cells if the attribute of the received data indicates that the received data has a high data-retention characteristic, each memory cell of the second group of resistive-type memory cells comprising a second feature size that is different than the first feature size.

### BRIEF DESCRIPTION OF THE DRAWINGS

Illustrative, non-limiting exemplary embodiments will be more clearly understood from the following detailed description taken in conjunction with the accompanying drawings.

FIG. 1 is a block diagram depicting an electronic system according to exemplary embodiments.

FIG. 2 is a block diagram depicting an example of the memory system in FIG. 1 according to exemplary embodiments.

FIG. 3 is a block diagram depicting an example of the resistive-type memory device in FIG. 2 according to exemplary embodiments.

FIGS. 4A to 4D are circuit diagrams of examples of the resistive-type memory cell in FIG. 3 according to exemplary embodiments.

FIG. 5 depicts an example of the first bank array in the resistive-type memory device of FIG. 3 according to exemplary embodiments.

FIG. 6A is a perspective view depicting the first resistive-type memory cell (referred to as a first STT-MRAM cell) in FIG. 5 according to exemplary embodiments.

FIG. 6B is a perspective view depicting the second resistive-type memory cell (referred to as a second STT-MRAM cell) in FIG. 5 according to exemplary embodiments.

FIGS. 7A and 7B depict block diagrams for describing a magnetization direction according to data written to the first MTJ element of FIG. 6A.

FIG. 8 depicts a block diagram for describing a write operation of the first STT-MRAM cell of FIG. 6A according to exemplary embodiments.

FIGS. 9A and 9B are block diagrams depicting first MTJ elements in the first STT-MRAM cell in FIG. 6A according to exemplary embodiments.

FIG. 10 is a block diagram depicting a first MTJ element in the first STT-MRAM cell in FIG. 6A according to exemplary embodiments.

FIGS. 11A and 11B are block diagrams depicting dual MTJ elements in the first STT-MRAM cell in FIG. 6A according to exemplary embodiments.

FIG. 12 depicts a layout of a resistive-type memory device according to exemplary embodiments.

FIG. 13 depicts a layout of the bank array in FIG. 12 according to exemplary embodiments.

FIG. 14 depicts an example of a portion of the bank array in FIG. 13 in detail.

FIG. 15 is a circuit diagram depicting the resistive-type memory device of FIG. 14 according to exemplary embodiments.

FIG. 16 depicts an arrangement of a resistive-type memory device according to exemplary embodiments.

FIG. 17 is a structural diagram depicting a resistive-type memory device according to exemplary embodiments.

FIG. 18 depicts configuration of the semiconductor integrated circuit layers in FIG. 17.

FIG. 19A is a block diagram depicting an integrated circuit (IC) including the resistive-type memory device according to exemplary embodiments.

FIG. 19B is a flow diagram of an exemplary embodiment of a method for storing data according to exemplary embodiments.

FIG. 20 is a block diagram depicting a mobile system including the resistive-type memory device according to exemplary embodiments.

### DETAILED DESCRIPTION OF THE EMBODIMENTS

Various exemplary embodiments will be described more fully hereinafter with reference to the accompanying drawings, in which some exemplary embodiments are shown. As used herein, the word “exemplary” means “serving as an example, instance, or illustration.” Any embodiment described herein as “exemplary” is not to be construed as necessarily preferred or advantageous over other embodiments.

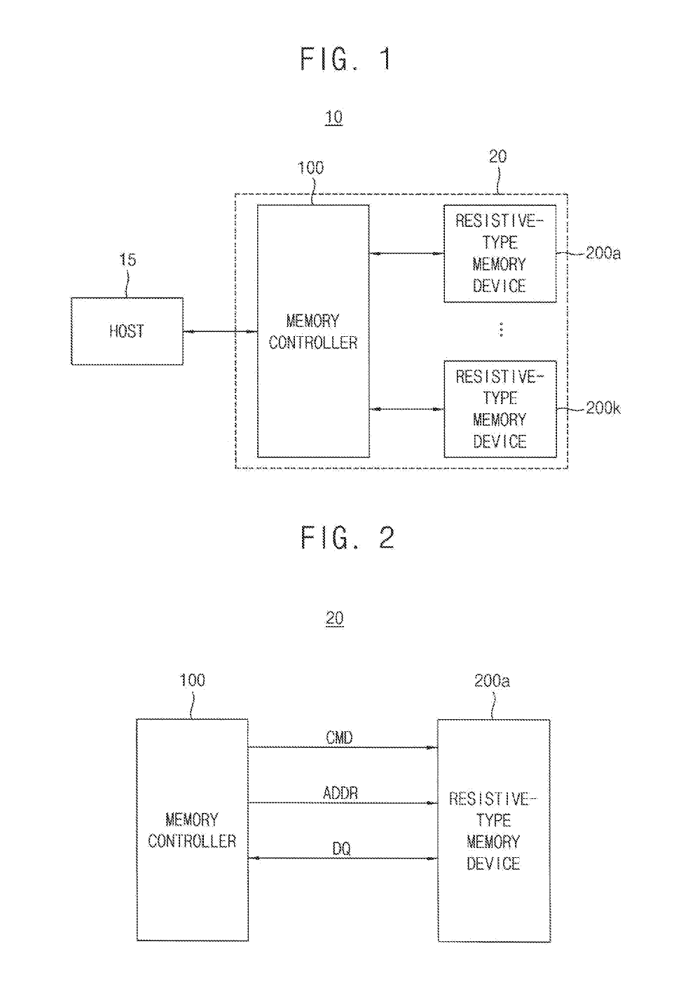

FIG. 1 is a block diagram depicting an electronic system according to exemplary embodiments.

Referring to FIG. 1, an electronic system 10 may include a host 15 and a memory system 20. The memory system 20 may include a memory controller 100 and a plurality of resistive-type memory devices 200a-200k.

The host 15 may communicate with the memory system 20 through various interface protocols, such as, but not limited to, Peripheral Component Interconnect-Express (PCIe), Advanced Technology Attachment (ATA), Serial ATA (SATA), Parallel ATA (PATA), or serial attached SCSI (SAS). Additionally, the host 15 may also communicate with the memory system 20 through interface protocols, such as, but not limited to, Universal Serial Bus (USB), Multi-Media Card (MMC), Enhanced Small Disk Interface (ESDI), or Integrated Drive Electronics (IDE).

The memory controller 100 may control an overall operation of the memory system 20. The memory controller 100 may control an overall data exchange between the host 20 and the plurality of resistive-type memory devices 200a-200k. For example, the memory controller 100 may write data in the plurality of resistive-type memory devices 200a-200k, or read data from the plurality of resistive-type memory devices 200a-200k in response to request from the host 15.

Additionally, the memory controller 100 may issue operational commands to the plurality of resistive-type memory devices 200a-200k for controlling the plurality of resistive-type memory devices 200a-200k.

In some embodiments, each of the plurality of resistive-type memory devices 200a-200k may be a memory device that includes resistive-type memory cells, such as a magnetic random access memory (MRAM), a resistive random access memory (RRAM), a phase-change random access memory (PRAM) and a ferroelectric random access memory (FRAM), etc.

In some embodiments, some of the plurality of resistive-type memory devices 200a-200k may include a first group of resistive-type memory cells and others of the plurality of resistive-type memory devices 200a-200k may include a second group of resistive-type memory cells. Each of the first group of resistive-type memory cells may have a first feature size and each of the second group of resistive-type memory cells may have a second feature size that may be greater than the first feature size.

Each of the first group of resistive-type memory cells may include a first magnetic tunnel junction (MTJ) element that has a relatively short switching time that is required for changing a magnetization direction of a magnetic layer in the first MTJ element. Accordingly, each of the first group of resistive-type memory cells may have a short data-retention time, that is, a low data-retention characteristic. Each of the second group of resistive-type memory cells may include a second magnetic tunnel junction (MTJ) element that has a relatively long switching time that is required for changing a magnetization direction of a magnetic layer in the second MTJ element. Accordingly, each of the second group of resistive-type memory cells may have a long data-retention time, that is, a high data-retention characteristic. However, energy required for changing a magnetization direction of the magnetic layer in the second MTJ element may be greater than the energy required for changing a magnetization direction of the magnetic layer in the first MTJ element, therefore, the power consumption for accessing the second group of resistive-type memory cells may be greater than the power consumption for accessing the first group of resistive-type memory cells. Therefore, the plurality of resistive-type memory devices 200a-200k may together have both a random access memory (RAM) characteristic that is associated with low power consumption and a nonvolatile characteristic that is associated with high data-retention characteristic.

An MRAM is a nonvolatile computer memory that is based on magnetoresistance. An MRAM is different from a volatile RAM in many aspects. An MRAM may retain all stored data even when power is turned off because an MRAM is a nonvolatile memory.

Although a nonvolatile RAM is generally slower than a volatile RAM, an MRAM has read and write response times that may be comparable with read and write response times of a volatile RAM. Unlike a conventional RAM that stores data as an electric charge, an MRAM stores data by using magnetoresistance elements. Generally, a magnetoresistance element may be made of two magnetic layers in which each magnetic layer has a magnetization.

An MRAM is a nonvolatile memory device that reads and writes data by using a magnetic tunnel junction pattern that includes two magnetic layers and an insulating film disposed between the two magnetic layers. A resistance value of the magnetic tunnel junction pattern may vary according to a magnetization direction of each of the magnetic layers. The MRAM may store or erase data by using the variation of the resistance value.

An MRAM using a spin-transfer torque (STT) phenomenon uses a method in which if a spin-polarized current flows in one direction, a magnetization direction of the magnetic layer is changed due to the spin transfer of electrons. A magnetization direction of one magnetic layer (pinned layer) may be fixed and a magnetization direction of the other magnetic layer (free layer) may vary according to a magnetic field generated by a programming or write current.

The magnetic field of the programming current may arrange the magnetization directions of the two magnetic layers to be in parallel or anti-parallel. In one embodiment, if the magnetization directions of the two magnetic layers are in parallel, a resistance between the two magnetic layers is in a low (“0”) state. If the magnetization directions of the two magnetic layers are in anti-parallel, a resistance between the two magnetic layers is in a high (“1”) state. Switching of the magnetization direction of the free layer with respect to the pinned layer results in a write operation of the MRAM, and the high or low state of the resistance of the MRAM may be read during a read operation of the MRAM.

Although the MRAM is nonvolatile and provides a quick response time, an MRAM cell has a limited scalability and may be sensitive to write disturbance as the size of an MRAM cell decreases. The programming, or write, current applied to switch between the high and low states of the resistance of the magnetic layers of the MRAM is typically high. Accordingly, when a plurality of cells are arranged in an MRAM array, a programming current that is applied to one memory cell may change a magnetic field of a free layer of an adjacent cell. Such a write disturbance may be prevented by using an STT phenomenon. A typical STT-MRAM may include MTJ element (MTJ) that is a magnetoresistive data storage device that includes two magnetic layers (a pinned layer and a free layer), and an insulating layer disposed between the two magnetic layers.

A programming current may flow through the MTJ. The pinned layer spin-polarizes electrons of the programming current, and a torque is generated by the spin-polarized electrons of the programming current as the programming current passes through the MTJ. The spin-polarized electrons of the programming current interact with the free layer and apply the torque to the free layer. If the torque of the spin-polarized electrons of the programming current passing through the MTJ is greater than a threshold switching current density, the torque applied by the spin-polarized electrons of the programming current may be sufficient to switch a magnetization direction of the free layer. The magnetization direction of the free layer may be changed to be parallel or anti-parallel to the pinned layer and a resistance state in the MTJ is changed accordingly.

The spin-polarized programming current of a STT-MRAM eliminates the necessity for an external magnetic field to switch the free layer in the magnetoresistive device. Additionally, as an STT-MRAM cell size scales smaller, the programming current is reduced and write disturbance may be reduced or prevented. An STT-MRAM may also have a high tunnel magnetoresistance ratio, and a read operation in a magnetic domain may be improved by allowing a high ratio between the high and low states.

An MRAM may therefore be an all-round memory device that has a low cost, a high capacity (like a dynamic random access memory (DRAM), operates at high speed (like a static random access memory (SRAM), and is nonvolatile (like a flash memory).

FIG. 2 is a block diagram depicting an example of the memory system in FIG. 1 according to exemplary embodiments.

In FIG. 2, only one resistive-type memory device 200a is depicted to be in communication with the memory controller 100 for convenience. While the details disclosed herein relate to resistive-type memory device 200a formed by STT-MRAM devices, the details may apply equally to the other resistive-type memory devices 200b-200k.

Referring to FIG. 2, the memory system 20 may include the memory controller 100 and the resistive-type memory device 200a. The memory controller 100 may unidirectionally transmit commands CMDs and addresses ADDRs to the resistive-type memory device 200a. The memory controller 100 may bidirectionally exchange data DQ with the resistive-type memory device 200a.

Referring to FIGS. 1 and 2, the memory controller 100 may input data DQ to the resistive-type memory device 200a or the resistive-type memory device 200a may output data DQ based on a request from the host 15.

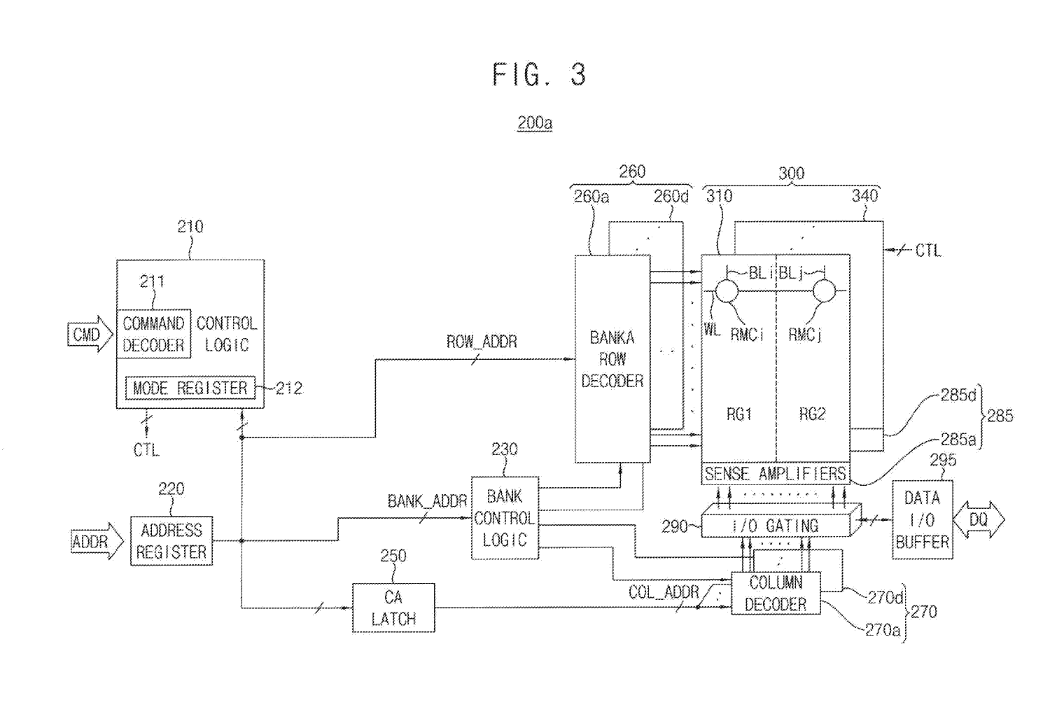

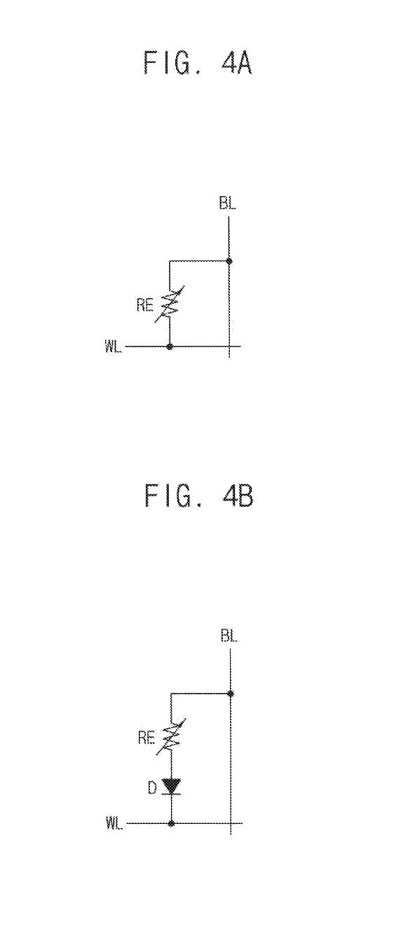

FIG. 3 is a block diagram depicting an example of the resistive-type memory device in FIG. 2 according to exemplary embodiments.

Referring to FIG. 3, the resistive-type memory device 200a may include a control logic circuit 210, an address register 220, a bank control logic 230, a column address (CA) latch 250, a row decoder 260, a column decoder 270, a memory cell array 300, a sense amplifier unit 285, an input/output (I/O) gating circuit 290, and a data input/output (I/O) buffer 295.

The memory cell array 300 may include first through fourth bank arrays 310-340 of which only the first bank array 310 and the fourth bank array 340 are explicitly depicted. The row decoder 260 may include first through fourth bank row decoders 260a-260d that are respectively coupled to the first through fourth bank arrays 310-340. The column decoder 270 may include first through fourth bank column decoders 270a-270d that are respectively coupled to the first through fourth bank arrays 310-340. The sense amplifier unit 285 may include first through fourth bank sense amplifiers 285a-285d that are respectively coupled to the first through fourth bank arrays 310-340. The first through fourth bank arrays 310-340, the first through fourth bank row decoders 260a-260d, the first through fourth bank column decoders 270a-270d and first through fourth bank sense amplifiers 285a-285d may form first through fourth banks. Each of the first through fourth bank arrays 310-340 may include a plurality of first resistive-type memory cells RMCi and second resistive-type memory cells RMCj. Each of first resistive-type memory cells RMCi and the second resistive-type memory cells RMCj may be coupled to a corresponding word-line and a corresponding bit-line. One of the first resistive-type memory cells RMCi is coupled to a corresponding bit-line BLi and one of the second resistive-type memory cells RMCj is coupled to a corresponding bit-line BLj. The first resistive-type memory cells RMCi may be also referred to as a first group of resistive-type memory cells and the second resistive-type memory cells RMCj may be also referred to as a second group of resistive-type memory cells.

Each of the first resistive-type memory cells RMCi may have a first feature size, and the second resistive-type memory cells RMCj may have a second feature size that is different from the first feature size. In one embodiment, the first feature size may be smaller or less than the second feature size.

The first resistive-type memory cells RMCi may be arranged in a first memory region RG1 in each of the first through fourth bank arrays 310-340, and the second resistive-type memory cells RMCj may be arranged in a second memory region RG2 in each of the first through fourth bank arrays 310-340.

In some exemplary embodiments, the first resistive-type memory cells RMCi may be arranged in some of the first through fourth bank arrays 310-340, and the second resistive-type memory cells RMCj may be arranged in others of the first through fourth bank arrays 310-340. That is, in some exemplary embodiments, the first resistive-type memory cells RMCi may be arranged only in selected bank arrays of the first through fourth bank arrays 310-340, and the second resistive-type memory cells RMCj may be arranged in selected other bank arrays of the first through fourth bank arrays 310-340.

Although the resistive-type memory device 200a is depicted in FIG. 3 as including four banks, the resistive-type memory device 200a may include any number of banks.

The address register 220 may receive an address ADDR that includes a bank address BANK_ADDR, a row address ROW_ADDR and a column address COL_ADDR from the memory controller 100. The address register 220 may provide the received bank address BANK_ADDR to the bank control logic 230, the received row address ROW_ADDR to the row address multiplexer 240, and the received column address COL_ADDR to the column address latch 250.

The bank control logic 230 may generate bank control signals in response to the bank address BANK_ADDR. One of the first through fourth bank row decoders 260a-260d corresponding to the bank address BANK_ADDR may be activated in response to the bank control signals, and one of the first through fourth bank column decoders 270a-270d corresponding to the bank address BANK_ADDR may be activated in response to the bank control signals.

The activated row decoder of the first through fourth bank row decoders 260a-260d may decode the row address ROW_ADDR from the address register 220, and may activate a word-line corresponding to the row address ROW_ADDR. For example, the activated bank row decoder may apply a word-line driving voltage to the word-line corresponding to the row address ROW_ADDR.

The column address (CA) latch 250 may receive the column address COL_ADDR from the address register 220, and may temporarily store the received column address COL_ADDR. In some embodiments, in a burst mode, the column address latch 250 may generate column addresses that increment from the received column address COL_ADDR. The column address latch 250 may apply the temporarily stored or the generated column address to the first through fourth bank column decoders 270a-270d.

The activated column decoder of the first through fourth bank column decoders 270a-270d may decode the column address COL_ADDR that is output from the column address latch 250, and may control the input/output gating circuit 290 in order to output data corresponding to the column address COL_ADDR.

The I/O gating circuit 290 may include a circuitry for gating input/output data. The I/O gating circuit 290 may further include read data latches (not shown) for storing data that is output from the first through fourth bank arrays 310-340, and write drivers for writing data to the first through fourth bank arrays 310-340.

Data DQ that is to be read from one bank array of the first through fourth bank arrays 310-340 may be sensed by a sense amplifier coupled to the one bank array from which the data is to be read, and may be stored in the read data latches. The data DQ stored in the read data latches may be provided to the memory controller 100 via the data I/O buffer 295. Data DQ that is to be written in one bank array of the first through fourth bank arrays 310-340 may be provided to the data I/O buffer 295 from the memory controller 100. The write driver may write the data DQ in one bank array of the first through fourth bank arrays 310-340.

The control logic circuit 210 may control operations of the resistive-type memory device 200a. For example, the control logic circuit 210 may generate control signals CTL for the resistive-type memory device 200a in order to perform a write operation or a read operation. The control logic circuit 210 may include a command decoder 211 that decodes a command CMD received from the memory controller 100 and a mode register 212 that sets an operational mode of the resistive-type memory device 200a. The mode register 212 may be programmed by mode register set (MRS) commands. The mode register 212 may generate mode signals according to a programmed operation mode.

For example, the command decoder 211 may generate the control signals CTL corresponding to the command CMD by decoding, for example, a write enable signal (/WE), a row address strobe signal (/RAS), a column address strobe signal (/CAS), a chip select signal (/CS), etc. (all not shown in FIG. 3). The control logic 210 may provide the control signals CTL to the memory cell array 300 and the control signal CTL may include column selection signals CSL and RCSL, sensing enable signals SAE and SAEB and a precharge control signal PC, which will be described later in connection with FIG. 15.

That is, the control logic circuit 210 may control access to the memory cell array 300 in response to the command CMD and the address ADDR from the memory controller 100.

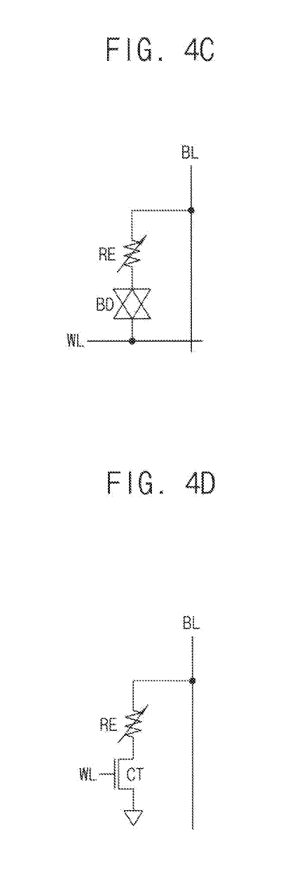

FIGS. 4A to 4D are circuit diagrams of examples of the resistive-type memory cell depicted in FIG. 3 at RMCi and RMCj according to exemplary embodiments.

FIG. 4A shows a resistive-type memory cell without a selection element, while FIGS. 4B to 4D show resistive-type memory cells that each comprise a selection element.

Referring to FIG. 4A, a resistive-type memory cell RMC may include a resistive element RE connected to a bit-line BL and a word-line WL. Such a resistive-type memory cell that has a structure that does not include a selection element may store data by a voltage applied between the bit-line BL and the word-line WL.

Referring to FIG. 4B, a resistive-type memory cell RMC may include a resistive element RE and a diode D connected in series. The resistive element RE may include a resistive material that is used for data storage. The diode D may be a selection element (or switching element) that supplies current to the resistive element RE or cuts off the current supply to the resistive element RE according to a bias of the word-line WL and the bit-line BL. The diode D may be coupled between the resistive element RE and word-line WL, and the resistive element RE may be coupled between the bit-line BL and the diode D. Positions of the diode D and resistive element RE may be interchangeable. The diode D may be turned on or turned off by a word-line voltage with respect to a bit-line voltage. Thus, a resistive memory cell may be not driven in which a voltage of a constant level or greater is supplied to an unselected word-line WL with respect to the bit-line BL voltage.

Referring to FIG. 4C, a resistive-type memory cell RMC may include a resistive element RE and a bidirectional diode BD. The resistive element RE may include a resistive material that is used for data storage. The bidirectional diode BD may be coupled between the resistive element RE and a word-line WL, and the resistive element RE may be coupled between a bit-line BL and the bidirectional diode BD. The positions of the bidirectional diode BD and the resistive element RE may be interchangeable. The bidirectional diode BD may block leakage current flowing to an unselected resistive-type memory cell.

Referring to FIG. 4D, a resistive-type memory cell RMC may include a resistive element RE and a transistor CT. The transistor CT may be a selection element (or switching element) that supplies current to the resistive element RE or cuts off the current supply to the resistive element RE according to a voltage of a word-line WL. The transistor CT may be coupled between the resistive element RE and a word-line, and the resistive element RE may be coupled between a bit-line BL and the transistor CT. The positions of the transistor CT and the resistive element RE may be interchangeable. The resistive-type memory cell may be selected or unselected depending on whether the transistor CT drive is turned on or turned off by the word-line WL.

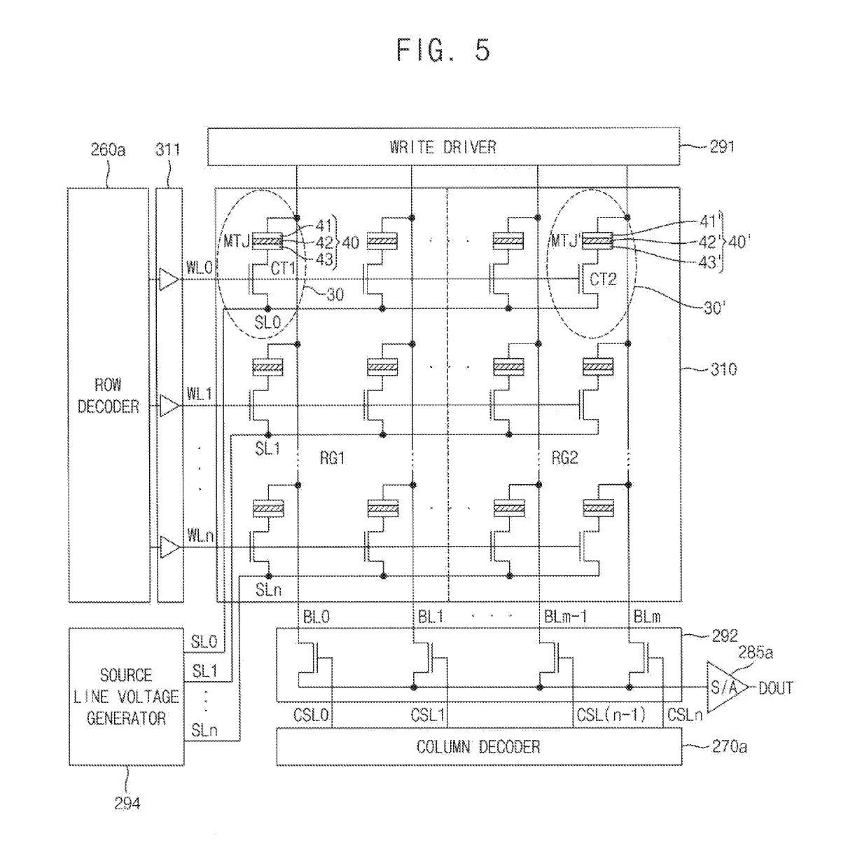

FIG. 5 depicts an example of the first bank array in the resistive-type memory device of FIG. 3 according to exemplary embodiments.

Referring to FIG. 5, the first bank array 310 may include a plurality of word-lines WL0 through WLn (in which n is a natural number that is greater than 1), a plurality of bit-lines BL0 through BLm (in which m is a natural number that is greater than 1), a plurality of source lines SL0 through SLn, a plurality of first resistive-type memory cells 30 and a plurality of second resistive-type memory cells 30′. The plurality of first resistive-type memory cells 30 and the plurality of second resistive-type memory cells 30′ are disposed at intersections between the word-lines WL0 through WLn and the bit-lines BL0 through BLm. The first resistive-type memory cells 30 may be disposed in a first memory region RG1 and the second resistive-type memory cells 30′ may be disposed in a second memory region RG2. Each of the first resistive-type memory cells 30 may be an STT-MRAM cell, and each of the second resistive-type memory cells 30′ may be an STT-MRAM cell.

The first resistive-type memory cell 30 may include a first MTJ element 40 that includes a magnetic material, and the second resistive-type memory cell 30′ may include a second MTJ element 40′.

Each of the first resistive-type memory cells 30 may include a first cell transistor CT1 and a first MTJ element 40. In one memory cell 30, a drain (a first electrode) of the first cell transistor CT1 may be connected to a pinned layer 43 of the first MTJ element 40. A free layer 41 of the first MTJ element 40 may be connected to the bit-line BL0, and a source (a second electrode) of the first cell transistor CT1 may be connected to the source line SL0. A gate of the first cell transistor CT1 may be connected to the word-line WL0.

Each of the second resistive-type memory cells 30′ may include a second cell transistor CT2 and a second MTJ element 40′. In one memory cell 30′, a drain (a first electrode) of the second cell transistor CT1′ may be connected to a pinned layer 43′ of the second MTJ element 40′. A free layer 41′ of the second MTJ element 40′ may be connected to the bit-line BLm, and a source (a second electrode) of the second cell transistor CT2 may be connected to the source line SL0. A gate of the second cell transistor CT2 may be connected to the word-line WL0.

Each of the first MTJ element 40 and the second MTJ element 40′ may be replaced by another resistive device, such as a phase-change random access memory (PRAM) that uses a phase-change material, a resistive random access memory (RRAM) that uses a variable-resistive material, such as a complex metal oxide, or a magnetic random access memory (MRAM) that uses a ferromagnetic material. Materials forming the resistive devices have resistance values that vary according to a size and/or a direction of a current or a voltage, and are nonvolatile and thus may maintain the resistance values even if the current or the voltage is off.

The word-line WL0 may be enabled by a first row decoder 260a, and may be connected to a word-line driver 311 that drives a word-line selection voltage. The word-line selection voltage activates the word-line WL0 in order to read or write logic states of the first MTJ element 40 and the second MTJ element 40′.

The source line SL0 is connected to a source line voltage generator 294. The source line voltage generator 294 may receive and decode an address signal and a read/write signal, and may generate a source line selection signal in the selected source line SL0. A ground reference voltage may be supplied to the unselected source lines SL1 through SLn.

The bit-line BL0 is connected to a column select circuit 24 that is driven by column selection signals CSL0 through CSLm. The column selection signals CSL0 through CSLm are selected by a column decoder 270a. For example, the selected column selection signal CSL0 turns on a column-select transistor in the column selection circuit 292, and selects the bit-line BL0. A logic state of the first MTJ element 40 may be read from the bit-line BL0 through a sense amplifier 285a. Alternatively, a write current applied through the write driver 291 may be transmitted to the selected bit-line BL0 and is written to the first MTJ element 40.

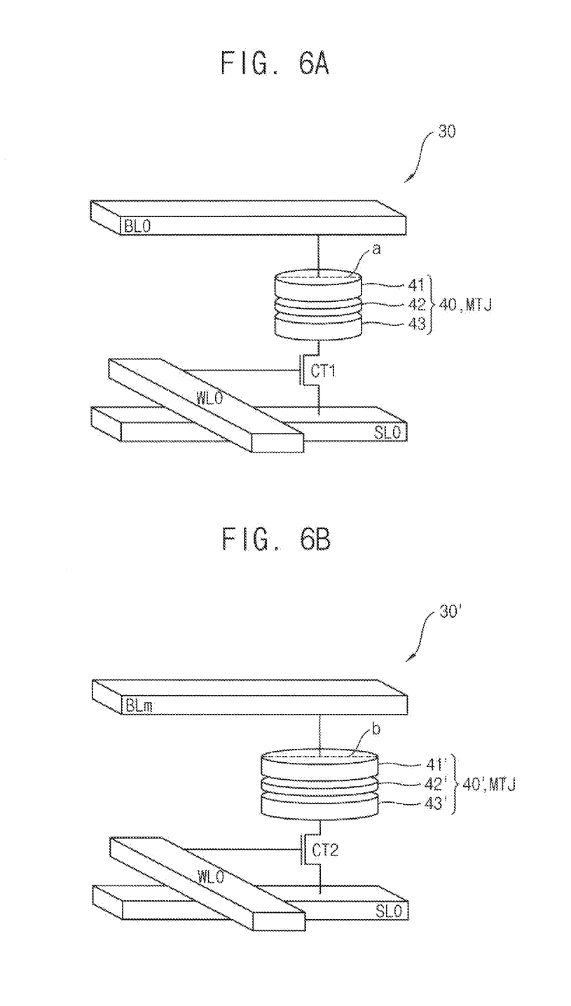

FIG. 6A is a perspective view depicting the first resistive-type memory cell 30 (referred to as a first STT-MRAM cell) in FIG. 5 according to exemplary embodiments.

Referring to FIG. 6A, the first STT-MRAM cell 30 may include the first MTJ element 40 and the first cell transistor CT1. A gate of the first cell transistor CT1 is connected to a word-line (for example, the word-line WL0), and one electrode of the first cell transistor CT1 is connected through the first MTJ element 40 to a bit-line (for example, the bit-line BL0). Also, the other electrode of the first cell transistor CT1 is connected to a source line (for example, the source line SL0). The first MTJ element 40 may have a cylindrical shape in which a diameter of the cylindrical shape may be “a” that is greater than zero. Although the cylindrical shape of the first MTJ element 40 is depicted as being round or substantially round, it should be understood that the cylindrical shapes of the first MTJ elements 40 in an array may differ slightly within manufacturing variations.

The first MTJ element 40 may include the free layer 41, the pinned layer 43, and a tunnel layer 42 that is disposed between the free layer 41 and the pinned layer 43. A magnetization direction of the pinned layer 43 may be fixed, and a magnetization direction of the free layer 41 may be parallel to or anti-parallel to the magnetization direction of the pinned layer 43 based on data written to the first MTJ element 40. The magnetization direction of the pinned layer 43 may be fixed by, for example, an anti-ferromagnetic layer (not shown).

In order to perform a write operation of the first STT-MRAM cell 30, a logic high voltage is applied to the word-line WL0 to turn on the first cell transistor CT1. A programming current, that is, a write current, is applied to the bit-line BL0 and the source line SL0. A direction of the write current is determined by a logic state of the first MTJ element 40.

In order to perform a read operation of the first STT-MRAM cell 30, a logic high voltage is applied to the word-line WL0 to turn on the cell transistor CT, and a read current is supplied to the bit-line BL0 and the source line SL0. Accordingly, a voltage that is developed at both ends of the first MTJ element 40, is detected by the sense amplifier 285a, and is compared to a reference voltage that is output from a reference voltage to determine a logic state of the MTJ element 40. Accordingly, data stored in the first MTJ element 40 may be detected.

FIG. 6B is a perspective view depicting the second resistive-type memory cell 30′ (referred to as a second STT-MRAM cell) in FIG. 5 according to exemplary embodiments.

Referring to FIG. 6B, the second STT-MRAM cell 30′ may include the second MTJ element 40′ and the second cell transistor CT2. A gate of the second cell transistor CT2 is connected to a word-line (for example, the word-line WL0), and one electrode of the second cell transistor CT2 is connected through the second MTJ element 40′ to a bit-line (for example, the bit-line BLm). Also, the other electrode of the second cell transistor CT2 is connected to a source line (for example, the source line SL0). The second MTJ element 40 may have a cylindrical shape in which a diameter of the cylindrical shape may be “b” that is greater than zero and greater than “a”. Although the cylindrical shape of the first MTJ element 40′ is depicted as being round or substantially round, it should be understood that the cylindrical shapes of the first MTJ elements 40′ in an array may differ slightly within manufacturing variations.

The second MTJ element 40′ may include the free layer 41′, the pinned layer 43′, and a tunnel layer 42′ disposed between the free layer 41′ and the pinned layer 43′. A magnetization direction of the pinned layer 43′ may be fixed, and a magnetization direction of the free layer 41′ may be parallel to or anti-parallel to the magnetization direction of the pinned layer 43′ based on data written to the first MTJ element 40′. The magnetization direction of the pinned layer 43′ may be fixed by, for example, an anti-ferromagnetic layer (not shown). A time that may be required for changing the magnetization direction of the pinned layer 43′ may be proportional to a size of the pinned layer 43′. That is, a switching characteristic of the magnetization direction of the pinned layer 43′ may be proportional to the diameter “b” of the second MTJ element 40′.

A time that is required for changing the magnetization direction of the pinned layer 43 of the first MTJ element 40 may be less than the time for required for changing the magnetization direction of the pinned layer 43′ of the second MTJ element 40′ because the diameter “b” of the second MTJ element 40′ is greater than the diameter “a” of the first MTJ element 40. Therefore, a time required for writing data in the first STT-MRAM cell 30 may be less than a time required for writing data in the second STT-MRAM cell 30′. Thus, the first STT-MRAM cell 30 may have a random-access characteristic associated with a short data-access time and a low power-consumption characteristic, and the second STT-MRAM cell 30′ may have a high nonvolatile characteristic associated with long data-retention time.

When an occupied area of the first memory region RG1 is substantially the same as an occupied area of the second memory region RG2, a first number of the first resistive-type memory cells coupled to a word-line may be greater than a second number of the second resistive-type memory cells 30′ coupled to the same word-line of the word-lines WL0-WLn.

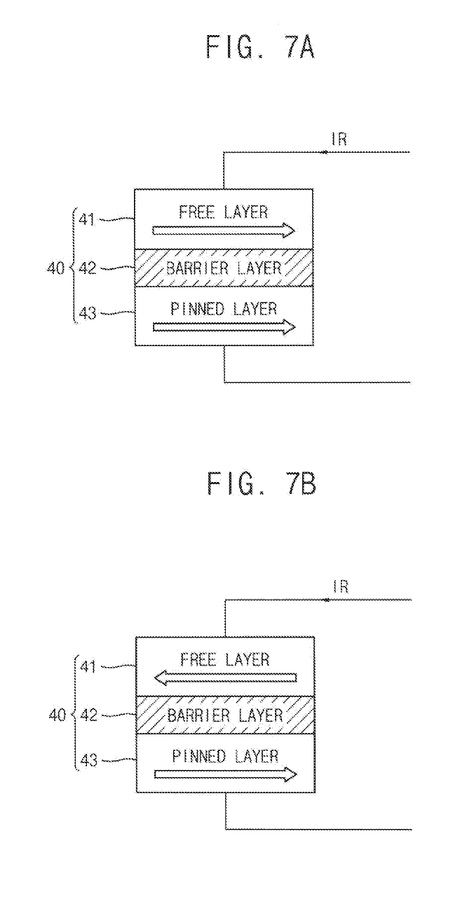

FIGS. 7A and 7B depict block diagrams for describing a magnetization direction according to data written to the first MTJ element of FIG. 6A.

A resistance value of the first MTJ element 40 may vary according to a magnetization direction of the free layer 41. When a read current IR flows through the MTJ 40, a data voltage is output based on the resistance value of the first MTJ element 40. Since the magnitude of the read current IR is much smaller than a magnitude of a write current, a magnetization direction of the free layer 41 is not changed by the read current IR.

Referring to FIG. 7A, a magnetization direction of the free layer 41 and a magnetization direction of the pinned layer 43 of the first MTJ element 40 are parallel. Accordingly, the MTJ element 40 may have a low resistance value. In this case, the first MTJ element 40 may read as a data “0”.

Referring to FIG. 7B, a magnetization direction of the free layer 41 and a magnetization direction of the pinned layer 43 of the first MTJ element 40 are anti-parallel. Accordingly, the first MTJ element 40 may have a high resistance value. In this case, the first MTJ element 40 may read as a data “1”.

Although the free layer 41 and the pinned layer 43 of the first MTJ 40 are horizontal magnetic layers, that is, magnetic layers having a magnetic direction that is horizontally oriented in FIGS. 7A and 7B, the present disclosure is not limited thereto and the free layer 41 and the pinned layer 43 may be, for example, vertical magnetic layers, that is, magnetic layers having a vertically oriented in FIGS. 7A and 7B.

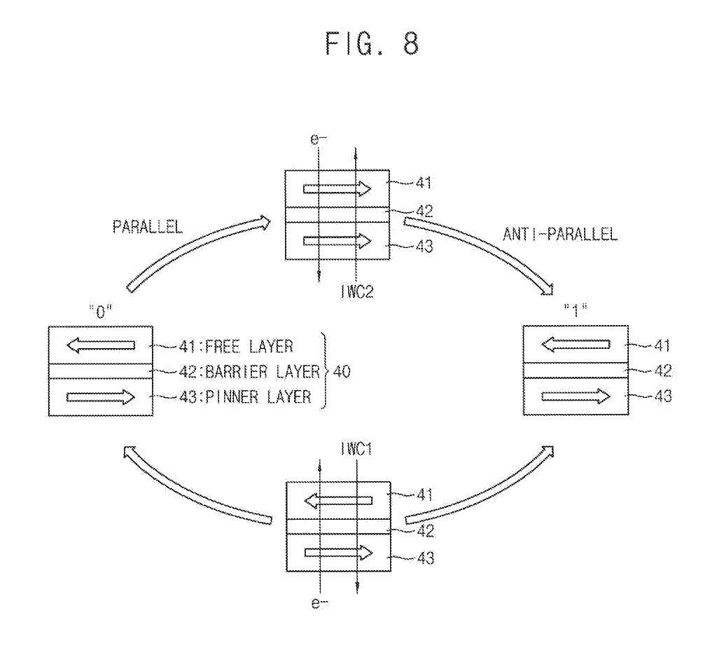

FIG. 8 depicts a block diagram for describing a write operation of the first STT-MRAM cell of FIG. 6A according to exemplary embodiments.

Referring to FIG. 8, a magnetization direction of the free layer 41 may be determined based on a direction of a write current IW flowing through the first MTJ element 40. For example, when a first write current IWC1 is supplied from the free layer 41 to the pinned layer 43, free electrons having the same spin direction as that of the pinned layer 43 apply a torque to the free layer 41. Accordingly, the free layer 41 may be magnetized to be parallel to the pinned layer 43.

When a second write current IWC2 is applied from the pinned layer 43 to the free layer 41, electrons having a spin direction that is opposite to the spin direction of the pinned layer 41 return to the free layer 43 and apply a torque. Accordingly, the free layer 41 may be magnetized to be anti-parallel to the pinned layer 43. That is, a magnetization direction of the free layer 41 of the first MTJ element 40 may be changed by an STT.

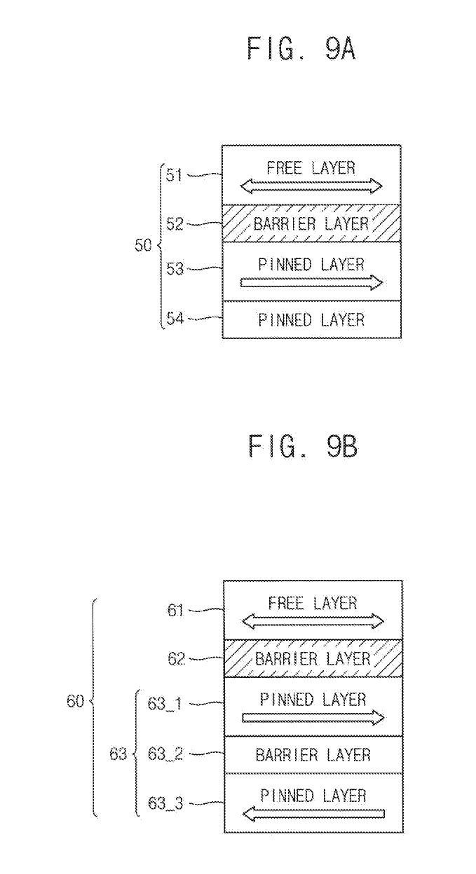

FIGS. 9A and 9B are block diagrams depicting first MTJ elements in the first STT-MRAM cell in FIG. 6A according to exemplary embodiments.

Referring to FIG. 9A, a first MTJ element 50 may include a free layer 51, a tunnel layer 52, a pinned layer 53, and an anti-ferromagnetic (pinned) layer 54. The free layer 51 may include a material having a variable magnetization direction. A magnetization direction of the free layer 51 may vary according to electrical/magnetic factors provided externally and/or internally to a memory cell. The free layer 51 may include a ferromagnetic material that includes, for example, cobalt (Co), iron (Fe), nickel (Ni), or a combination thereof. For example, the free layer 51 may include FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe Fe₂O₃, MgOFe Fe₂O₃, EuO, Y₃Fe₅O₁₂, or a combination thereof.

The tunnel layer 52, also referred to as a barrier layer 52, may have a thickness in a direction between the free layer 51 and the pinned layer 53 that is less than a spin-diffusion distance. The tunnel layer 52 may include a non-magnetic material. For example, the tunnel layer 52 may include magnesium (Mg), titanium (Ti), aluminum (Al), magnesium-zinc (MgZn) oxide, magnesium-boron (MgB) oxide, Ti nitride, vanadium (V) nitride, or a combination thereof.

The pinned layer 53 may have a magnetization direction fixed by the anti-ferromagnetic layer 54. Also, the pinned layer 53 may include a ferromagnetic material. For example, the pinned layer 53 may include CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe Fe₂O₃, MgOFe Fe₂O₃, EuO, Y₃Fe₅O₁₂, or a combination thereof.

The anti-ferromagnetic layer 54 may include an anti-ferromagnetic material. For example, the anti-ferromagnetic layer 54 may include PtMn, IrMn, MnO, MnS, MnTe, MnF₂, FeCl₂, FeO, CoCl₂, CoO, NiCl₂, NiO, Cr, or a combination thereof.

A stray field may be generated at an edge of the ferromagnetic material because each of the free layer 51 and the pinned layer 53 of the first MTJ element 50 may be formed from a ferromagnetic material. The stray field may reduce magnetoresistance or increase resistive magnetism of the free layer 51. Additionally, the stray field may affect switching characteristics, thereby resulting in asymmetric switching. Accordingly, a structure for reducing or controlling a stray field generated at the ferromagnetic material in the MTJ element 50 may be used.

Referring to FIG. 9B, a pinned layer 63 of a first MTJ element 60 may be formed from a synthetic anti-ferromagnetic (SAF) material. The pinned layer 63 may include a first ferromagnetic layer 63_1, a coupling layer 63_2, and a second ferromagnetic layer 63_3. Each of the first and second ferromagnetic layers 63_1 and 63_3 may include CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe Fe₂O₃, MgOFe Fe₂O₃, EuO, Y₃Fe₅O₁₂, or a combination thereof. In this case, a magnetization direction of the first ferromagnetic layer 63_1 and a magnetization direction of the second ferromagnetic layer 63_3 are different from each other, and are fixed. The coupling layer 63_2 may include, for example, ruthenium (Ru).

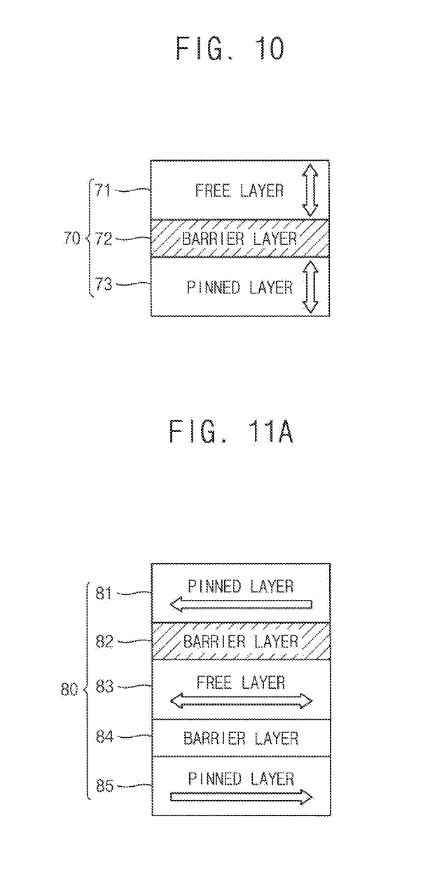

FIG. 10 depicts a block diagram illustrating a first MTJ element in the first STT-MRAM cell in FIG. 6A according to exemplary embodiments.

Referring to FIG. 10, a magnetization direction of the first MTJ element 70 is vertical and a direction of movement of a current and a magnetization easy-axis are substantially parallel to each other. The first MTJ element 70 includes a free layer 71, a tunnel layer 72, and a pinned layer 73. A resistance value of the first MTJ element 70 is small when a magnetization direction of the free layer 71 and a magnetization direction of the pinned layer 73 are parallel to each other, and, is large when a magnetization direction of the free layer 71 and a magnetization direction of the pinned layer 73 are anti-parallel to each other. Data may be stored in the MTJ element 70 based on the resistance value.

In order to realize the first MTJ element 70 having a vertical magnetization direction, each of the free layer 71 and the pinned layer 73 may be formed from a material having a high magnetic-anisotropy energy. Examples of the material having a high magnetic-anisotropy energy include an amorphous rare-earth element alloy, a multi-layer thin film, such as (Co/Pt)n or (Fe/Pt)n, and an ordered-lattice material having an L10 crystal structure. For example, the free layer 71 may be formed from an ordered alloy, and may include Fe, Co, Ni, palladium (Pa), platinum (Pt) or a combination thereof. Alternatively, the free layer 71 may include a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, or a combination thereof. Such alloys may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀ in terms of quantitative chemistry.

The pinned layer 73 may be formed from an ordered alloy, and may include Fe, Co, Ni, Pa, Pt, or a combination thereof. For example, the pinned layer 73 may include a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, or a combination thereof. Such alloys may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀ in terms of quantitative chemistry.

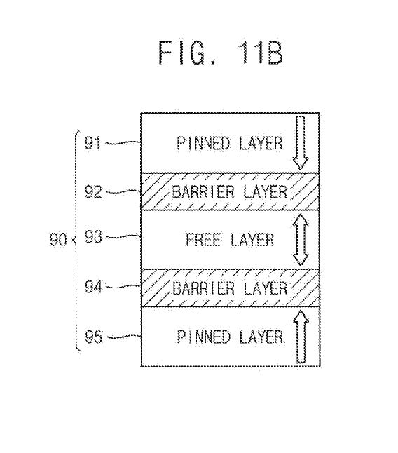

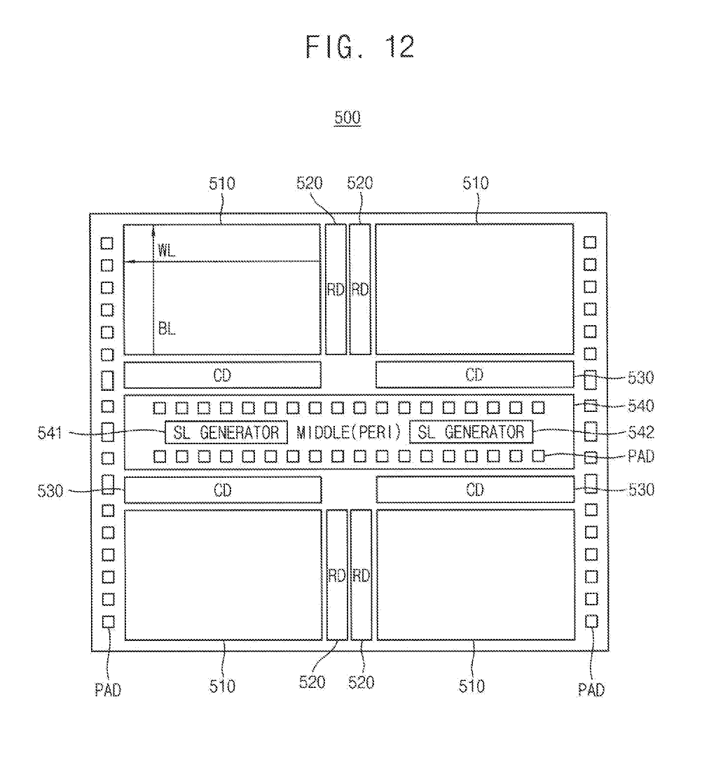

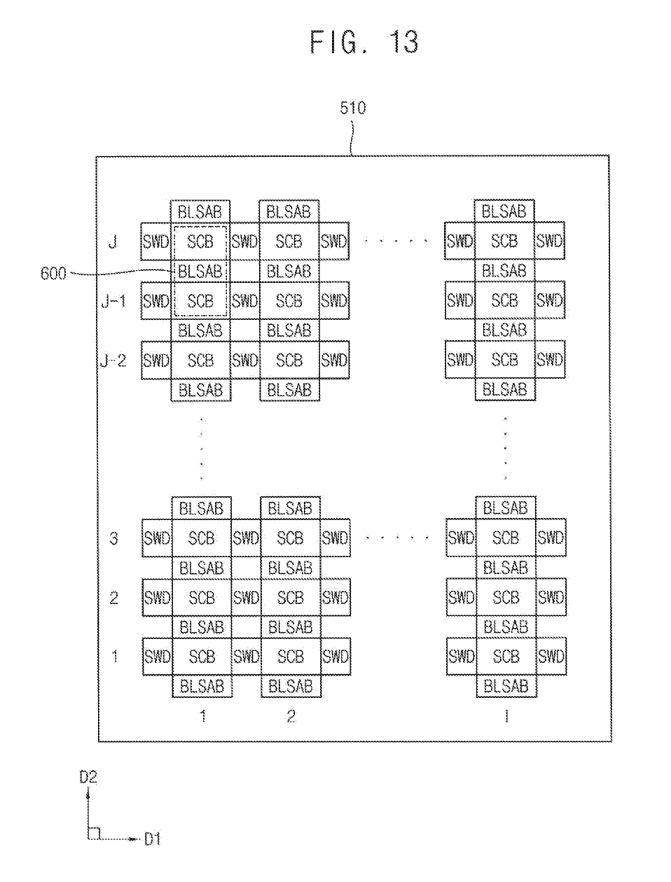

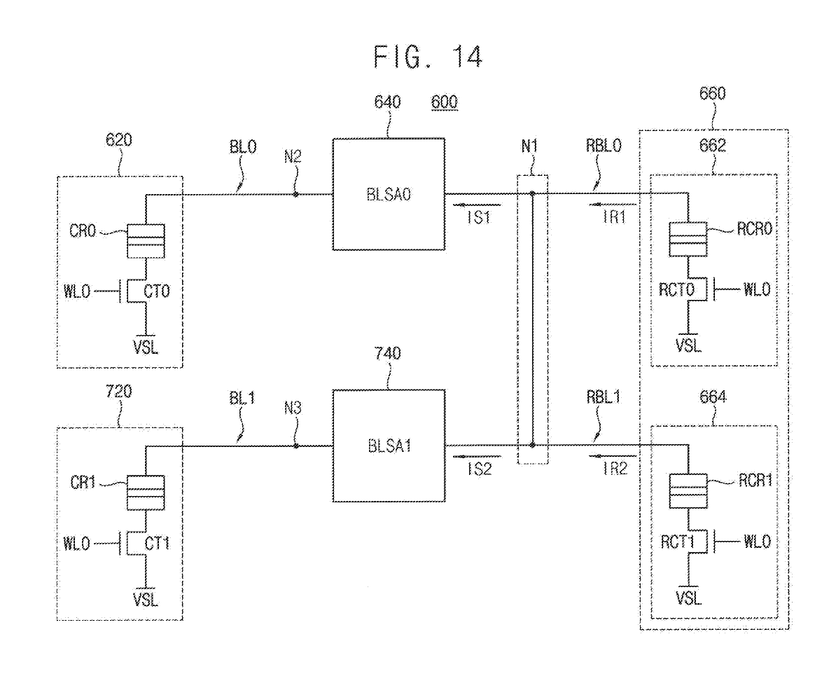

FIGS. 11A and 11B are block diagrams depicting dual MTJ elements in the first STT-MRAM cell in FIG. 6A according to exemplary embodiments. A dual MTJ is configured to include a tunnel layer and a pinned layer that are disposed at both ends of a free layer.

Referring to FIG. 11A, a dual MTJ element 80 having a horizontal magnetization direction may include a first pinned layer 81, a first tunnel layer 82, a free layer 83, a second tunnel layer 84, and a second pinned layer 85. Materials forming the first and second pinned layers 81 and 85 may be similar to the materials forming the pinned material 53 of FIG. 9A. Materials forming the first and second tunnel layers 82 and 84 may be similar to the materials forming the tunnel layer 52 of FIG. 9A. A material forming the free layer 83 may be similar to a material forming the free layer 51 of FIG. 7A.

When a magnetization direction of the first pinned layer 81 and a magnetization direction of the second pinned layer 85 are fixed in opposite directions, magnetic forces produced by the first and second pinned layers 81 and 85 are substantially counterbalanced. Accordingly, the dual MTJ element 80 may perform a write operation by using a current having a smaller magnitude than a current used by a general MTJ element.

Since the dual MTJ element 80 provides a higher resistance during a read operation due to the second tunnel layer 84, a more accurate data value may be obtained.

Referring to FIG. 11B, a dual MTJ element 90 having a vertical magnetization direction includes a first pinned layer 91, a first tunnel layer 92, a free layer 93, a second tunnel layer 94, and a second pinned layer 95. Materials forming the first and second pinned layers 91 and 95 may be similar to the materials forming the pinned layer 73 of FIG. 10. Materials forming the first and second tunnel layers 92 and 94 may be similar to the materials forming the tunnel layer 72 of FIG. 10. A material forming the free layer 93 may be similar to a material forming the free layer 71 of FIG. 10.

In this case, when a magnetization direction of the first pinned layer 91 and a magnetization direction of the second pinned layer 95 are fixed in opposite directions, magnetic forces by the first and second pinned layers 91 and 95 substantially counterbalance. Accordingly, the dual MTJ element 90 may perform a write operation by using a current having a magnitude that is less than a current used for a general MTJ element.

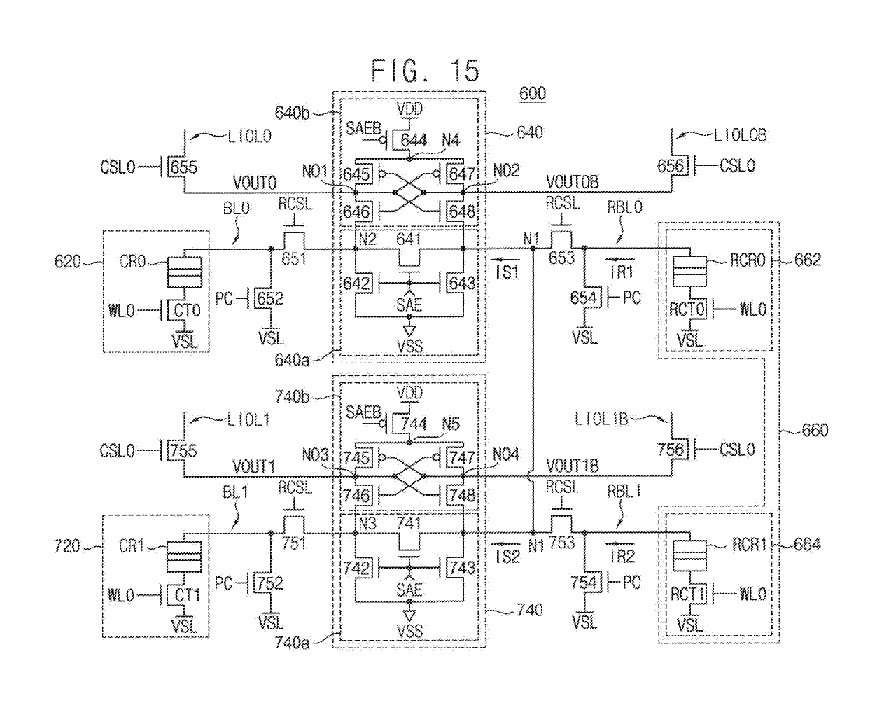

FIG. 12 depicts a layout of a resistive-type memory device according to exemplary embodiments.

Referring to FIG. 12, a resistive-type memory device 500 may include four bank arrays 510. A plurality of sub array blocks (not indicated in FIG. 12) that include a plurality of STT-MRAM cells may be disposed in each of the bank arrays 510. A row decoder 520 and a column decoder 530 may be disposed adjacent to each of the bank arrays 510. Also, pads PAD used to communicate with an external device may be disposed in peripheral regions disposed at the edges and the center of the resistive-type memory device 500. Furthermore, source line (SL) voltage generators 541 and 542 may be disposed in the peripheral region disposed in the center of the resistive-type memory device 500. The row decoders (RD) 520, the column decoders (CD) 530, and the source line voltage generators 541 and 542 may form peripheral circuits.

Although FIG. 12 depicts an embodiment in which two source line voltage generators 541 and 542 are provided, source line voltage generators may be provided in equal number to the number of bank arrays 510 so that source line driving voltages may be respectively applied to the bank arrays 510.

The row decoders 520 may be disposed in a word-line direction from the resistive-type memory device 500, while the column decoders 530 may be disposed in a bit-line direction from the memory device 500. Furthermore, the row decoders 520 allocated respectively to two adjacent bank arrays 1310 may be disposed adjacent to each other and share one or more control lines (not shown) therebetween.

FIG. 13 depicts a layout of a bank array in FIG. 12 according to exemplary embodiments.

Referring to FIG. 13, in the bank array 510, I sub array blocks SCB may be disposed, or arranged, in a first direction D1, and J sub array blocks SCB may be disposed, or arranged, in a second direction D2 that is orthogonal or substantially orthogonal to the first direction D1. A plurality of bit-lines, a plurality of word-lines, and a plurality of STT-MRAM cells may be disposed in each of the sub array blocks SCB. The plurality of STT-MRAM cells may be disposed at intersections between the bit-lines and the word-lines.

I+1 sub word-line driver regions SWD may be disposed between the sub array blocks SCB in the first direction D1. Sub word-line drivers may be disposed in the sub word-line driver regions SWD.

J+1 bit-line sense amplifier regions BLSAB may be disposed between the sub array blocks SCB in the second direction D2. Bit-line sense amplifier circuits to sense data stored in resistive-type memory cells may be disposed in the bit-line sense amplifier regions BLSAB. The first STT-MRAM cells 40 of FIG. 6A may be arranged in one sub array block SCB of two sub array blocks 600 that share one bit-line sense amplifier region BLSAB. The second STT-MRAM cells 40′ of FIG. 6B may be arranged in the other sub array block SCB of two sub array blocks 600 that share the one bit-line sense amplifier region BLSAB. The first resistive-type memory cells, each having a first feature size, may be arranged in one sub array block SCB of two sub array blocks 600 that share one bit-line sense amplifier region BLSAB. The second resistive-type memory cells, each having a second feature size, may be arranged in the other sub array block SCB of two sub array blocks 600 that share the one bit-line sense amplifier region BLSAB. Therefore, one sub array block SCB that shares one bit-line sense amplifier region BLSAB may provide a low power characteristic in a data-write operation and a data-read operation, and the other sub array block SCB that shares one bit-line sense amplifier region BLSAB may provide a high data-retention characteristic and reliability in a data-write operation and a data-read operation.

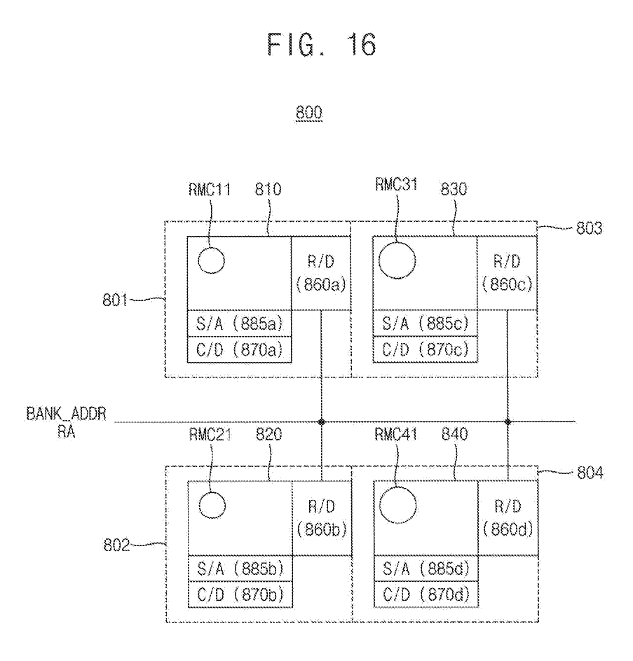

FIG. 14 depicts an example of a portion of the bank array in FIG. 13 in detail.

Referring to FIGS. 13 and 14, in a portion 600 of the bank array 510, i.e., the resistive-type memory device includes a first resistive-type memory cell 620, a second resistive-type memory cell 720, a reference current generator 660, a first bit-line sense amplifier 640 and a second bit-line sense amplifier 740.

The first resistive-type memory cell 620 may be connected to a first bit-line BL0. The first resistive-type memory cell 620 may store first data. The first resistive-type memory cell 620 may include a first resistive element CR0 and a first cell transistor CT0. The first resistive element CR0 may have a first terminal and a second terminal, and the first terminal of the first resistive element CR0 may be connected to the first bit-line BL0. The first cell transistor CT0 may have a first electrode (e.g., a source electrode) connected to the second terminal of the first resistive element CR0, a gate electrode connected to a first word-line WL0, and a second electrode (e.g., a drain electrode) connected to a source line voltage VSL.

The second resistive-type memory cell 720 may be connected to a second bit-line BL1. The second resistive-type memory cell 720 may store second data. The second resistive-type memory cell 720 may include a second resistive element CR1 and a second cell transistor CT1. The second resistive element CR1 may have a first terminal and a second terminal, and the first terminal of the second resistive element CR1 may be connected to the second bit-line BL1. The second cell transistor CT1 may have a first electrode connected to the second terminal of the second resistive element CR1, a gate electrode connected to the first word-line WL0, and a second electrode connected to the source line voltage VSL.

Each of the first resistive-type memory cell 620 and the second resistive-type memory cell 720 may have a first feature size. Each of the first resistive-type memory cell 620 and the second resistive-type memory cell 720 may include the first STT-MRAM cell 30 of FIG. 6A, and each of the first resistive element CR0 and the second resistive element CR1 may include the first MTJ element 40 of FIG. 6A.

The reference current generator 660 may be connected to a first node N1. The reference current generator 660 may respectively generate a first reference current IR1 and a second reference current IR2 and the first and second reference currents IR1 and IR2 may be applied to the first node N1. A magnitude of the second reference current IR2 may be different from a magnitude of the first reference current IR1.

The reference current generator 660 may include a first reference resistive-type memory cell 662 and a second reference resistive-type memory cell 664. The first reference resistive-type memory cell 662 may be connected to a first reference bit-line RBL0, and may store first reference data having a first logic level. The second reference resistive-type memory cell 664 may be connected to a second reference bit-line RBL1, and may store second reference data having a second logic level. The second logic level may be different from the first logic level. For example, the first logic level may correspond to a logic high level (e.g., “1”), and the second logic level may correspond to a logic low level (e.g., “0”). If the first logic level corresponds to the logic high level and the second logic level corresponds to the logic low level, the magnitude of the first reference current IR1 may be less than the magnitude of the second reference current IR2.

The first reference resistive-type memory cell 662 may include a first reference resistive element RCR0 and a first reference cell transistor RCT0. The first reference resistive element RCR0 may have a first terminal and a second terminal. The first terminal of the first reference resistive element RCR0 may be connected to the first reference bit-line RBL0. The first reference cell transistor RCT0 may have a first electrode connected to the second terminal of the first reference resistive element RCR0, a gate electrode connected to the first word-line WL0, and a second electrode connected to the source line voltage VSL.

The second reference resistive-type memory cell 664 may include a second reference resistive element RCR1 and a second reference cell transistor RCT1. The second reference resistive element RCR1 may have a first terminal and a second terminal. The first terminal of the second reference resistive element RCR1 may be connected to the second reference bit-line RBL1. The second reference cell transistor RCT1 may have a first electrode connected to the second terminal of the second reference resistive element RCR1, a gate electrode connected to the first word-line WL0, and a second electrode connected to the source line voltage VSL.

Each of the first reference resistive-type memory cell 662 and the second reference resistive-type memory cell 664 may have a second feature size. Each of the first reference resistive-type memory cell 662 and the second reference resistive-type memory cell 664 may include the second STT-MRAM cell 30′ of FIG. 6B. Each of the first reference resistive element RCR0 and the second reference resistive element RCR1 may include the second MTJ element 40′ of FIG. 6B.

The first bit-line sense amplifier 640 may be connected to the first node N1 and may be connected to the first bit-line BL0 at a second node N2. The first bit-line sense amplifier 640 senses the first data stored in the first resistive-type memory cell 620 based on a first sensing current IS1. The first sensing current IS1 is generated based on the first and second reference currents IR1 and IR2, and is provided from the first node N1.

The second bit-line sense amplifier 740 may be connected to the first node N1 and may be connected to the second bit-line BL1 at a third node N3. The second bit-line sense amplifier 740 senses the second data stored in the second resistive-type memory cell 720 based on a second sensing current IS2. The second sensing current IS2 is generated based on the first and second reference currents IR1 and IR2 and is provided from the first node N1. The magnitude of the second sensing current IS2 is substantially the same as the magnitude of the first sensing current IS1.

As depicted in FIG. 14, the first reference bit-line RBL0 and the first reference resistive type memory cell 662 may be substantially symmetrical to the first bit-line BL0 and the first resistive-type memory cell 620 with respect to the first bit-line sense amplifier 640. The second reference bit-line RBL1 and the second reference resistive-type memory cell 664 may be substantially symmetrical to the second bit-line BL1 and the second resistive-type memory cell 720 with respect to the second bit-line sense amplifier 740.

In some example embodiments, a total reference current may be obtained by adding the second reference current IR2 to the first reference current IR1 at the first node N1. The first and second sensing currents IS1 and IS2 may be generated by dividing (e.g., shunting) the total reference current into the first and second sensing currents IS1 and IS2 based on a first load and a second load. The first load may be based on the first resistive-type memory cell 620 and the first bit-line sense amplifier 640, and the second load may be based on the second resistive-type memory cell 220 and the second bit-line sense amplifier 740. As depicted in FIG. 14, the second resistive-type memory cell 720 may have a structure that is substantially the same as the structure of the first resistive-type memory cell 620. Additionally, as will be described below in connection with FIG. 15, the second bit-line sense amplifier 740 may have a structure that is substantially the same as the structure of the first bit-line sense amplifier 640. Therefore, the first load may be substantially the same as the second load, and thus the magnitude of the first sensing current IS1 may be substantially the same as the magnitude of the second sensing current IS2. Each of the magnitude of the first sensing current IS1 and the magnitude of the second sensing current IS2 may be substantially the same as a half of the magnitude of the total reference current. In other words, the first sensing current IS1 and the second sensing current IS2 may be represented by Equation 1.

IS1=IS2=(IR1+IR2)/2 (1)

In some example embodiments, the first and second sensing currents IS1 and IS2 may be generated substantially simultaneously, and thus the first and second data may be sensed substantially simultaneously.

The resistive-type memory device 600 may include two bit-line sense amplifiers 640 and 740 that are connected to the first node N1 and have the substantially same structure. A pair of the reference bit-lines RBL0 and RBL1 and a pair of the reference resistive-type memory cells 662 and 664 that store different reference data may be shared by two bit-line sense amplifiers 640 and 740. The reference currents IR1 and IR2 generated from the reference resistive-type memory cells 662 and 664 may be summed at the first node N1 to generate the total reference current, and the total reference current may be divided at the first node N1 to generate the sensing currents IS1 and IS2. Thus, the resistive-type memory device 600 may efficiently generate the sensing currents IS1 and IS2 that have the substantially same magnitude (e.g., level) without any additional circuitry (e.g., a current mirror). Accordingly, the resistive-type memory device 600 may have a relatively high degree of integration and a relatively high data-sensing performance. Additionally, the resistive-type memory device 600 may stably provide the reference currents IR1 and IR2 because each of the reference resistive-type memory cells 662 and 664 has a second feature size.

FIG. 15 is a circuit diagram depicting the resistive-type memory device of FIG. 14 according to exemplary embodiments.

Referring to FIG. 15, the resistive-type memory device 600 includes a first resistive-type memory cell 620, a second resistive-type memory cell 720, a reference current generator 660, a first bit-line sense amplifier 640 and a second bit-line sense amplifier 740. The resistive-type memory device 600 may further include first through fourth bit-line connectors 651, 653, 751 and 753, first through fourth precharge circuits 652, 654, 752 and 754, and first through fourth column gating circuits 655, 656, 755 and 756.

As described above in connection with FIG. 14, each of the first and second resistive-type memory cells 620 and 720 may respectively include the first and second resistive elements CR0 and CR1, and the first and second cell transistors CT0 and CT1. The reference current generator 660 may include the first and second reference resistive-type memory cells 662 and 664. Each of the first and second reference resistive-type memory cells 662 and 664 may respectively include the first and second reference resistive elements RCR0 and RCR1 and the first and second reference cell transistors RCT0 and RCT1.

The first bit-line sense amplifier 640 may include a first sensing circuit 640a and a second sensing circuit 640b. The first sensing circuit 640a may be connected to the first node N1 and the second node N2, and may operate in response to a sensing enable signal SAE. The second sensing circuit 640b may be connected to the first node N1 and the second node N2, and may operate in response to an inverted signal SAEB of the sensing enable signal SAE. The second sensing circuit 640b may include a first output node NO1 and a second output node NO2 that output a first result of sensing the first data (e.g., first output voltages VOUT0/VOUT0B). The second sensing circuit 640b may include, for example, a cross-coupled latch structure.

The first sensing circuit 640a may include a first n-channel metal oxide semiconductor (NMOS) transistor 641, a second NMOS transistor 642 and a third NMOS transistor 643. The first NMOS transistor 641 may be connected between the first node N1 and the second node N2, and may have a gate electrode that receives the sensing enable signal SAE. The second NMOS transistor 642 may be connected between the second node N2 and a ground voltage VSS, and may have a gate electrode that receives the sensing enable signal SAE. The third NMOS transistor 643 may be connected between the first node N1 and the ground voltage VSS, and may have a gate electrode that receives the sensing enable signal SAE.

The second sensing circuit 640b may include a first p-channel metal oxide semiconductor (PMOS) transistor 644, a second PMOS transistor 645, a fourth NMOS transistor 646, a third PMOS transistor 647 and a fifth NMOS transistor 648. The first PMOS transistor 644 may be connected between a power supply voltage VDD and a fourth node N4, and may have a gate electrode that receives the inverted signal SAEB of the sensing enable signal SAE. The second PMOS transistor 645 may be connected between the fourth node N4 and the first output node NO1, and may have a gate electrode connected to the second output node NO2. The fourth NMOS transistor 646 may be connected between the first output node NO1 and the second node N2, and may have a gate electrode connected to the second output node NO2. The third PMOS transistor 647 may be connected between the fourth node N4 and the second output node NO2, and may have a gate electrode connected to the first output node NO1. The fifth NMOS transistor 648 may be connected between the second output node NO2 and the first node N1, and may have a gate electrode connected to the first output node NO1.

The second bit-line sense amplifier 740 may have a structure substantially the same as the structure of the first bit-line sense amplifier 640. For example, the second bit-line sense amplifier 740 may include a third sensing circuit 740a and a fourth sensing circuit 740b. The third sensing circuit 740a may be connected to the first node N1 and the third node N3, and may operate in response to the sensing enable signal SAE. The fourth sensing circuit 740b may be connected to the first node N1 and the third node N3, and may operate in response to the inverted signal SAEB of the sensing enable signal SAE. The fourth sensing circuit 740b may include a third output node NO3 and a fourth output node NO4 that output a second result of sensing the second data (e.g., second output voltages VOUT1/VOUT1B).

The third sensing circuit 740a may include a sixth NMOS transistor 741, a seventh NMOS transistor 742 and a eighth NMOS transistor 743. The sixth NMOS transistor 741 may be connected between the first node N1 and the third node N3, and may have a gate electrode that receives the sensing enable signal SAE. The seventh NMOS transistor 742 may be connected between the third node N3 and the ground voltage VSS, and may have a gate electrode that receives the sensing enable signal SAE. The eighth NMOS transistor 743 may be connected between the first node N1 and the ground voltage VSS, and may have a gate electrode that receives the sensing enable signal SAE.

The fourth sensing circuit 740b may include a fourth PMOS transistor 744, a fifth PMOS transistor 745, a ninth NMOS transistor 746, a sixth PMOS transistor 747 and a tenth NMOS transistor 748. The fourth PMOS transistor 744 may be connected between the power supply voltage VDD and a fifth node N5, and may have a gate electrode that receives the inverted signal SAEB of the sensing enable signal SAE. The fifth PMOS transistor 745 may be connected between the fifth node N5 and the third output node NO3, and may have a gate electrode connected to the fourth output node NO4. The ninth NMOS transistor 746 may be connected between the third output node NO3 and the third node N3, and may have a gate electrode connected to the fourth output node NO4. The sixth PMOS transistor 747 may be connected between the fifth node N5 and the fourth output node NO4, and may have a gate electrode connected to the third output node NO3. The tenth NMOS transistor 748 may be connected between the fourth output node NO4 and the first node N1, and may have a gate electrode connected to the third output node NO3.

The first bit-line connector 651 may selectively connect the first bit-line BL0 with the second node N2 based on a read column selection signal RCSL. The second bit-line connector 653 may selectively connect the first reference bit-line RBL0 with the first node N1 based on the read column selection signal RCSL. The third bit-line connector 751 may selectively connect the second bit-line BL1 with the third node N3 based on the read column selection signal RCSL. The fourth bit-line connector 753 may selectively connect the second reference bit-line RBL1 with the first node N1 based on the read column selection signal RCSL.

The first precharge circuit 652 may precharge the first bit-line BL0 to the source line voltage VSL based on a precharge control signal PC. The second precharge circuit 654 may precharge the first reference bit-line RBL0 to the source line voltage VSL based on the precharge control signal PC. The third precharge circuit 752 may precharge the second bit-line BL1 to the source line voltage VSL based on the precharge control signal PC. The fourth precharge circuit 754 may precharge the second reference bit-line RBL1 to the source line voltage VSL based on the precharge control signal PC.

The first column gating circuit 655 may selectively connect the first output node NO1 to a first local I/O line LIOL0 based on a first column selection signal CSL0. The second column gating circuit 656 may selectively connect the second output node NO2 to a second local I/O line LIOL0B based on the first column selection signal CSL0. The third column gating circuit 755 may selectively connect the third output node NO3 to a third local I/O line LIOL1 based on the first column selection signal CSL0. The fourth column gating circuit 756 may selectively connect the fourth output node NO4 to a fourth local I/O line LIOL1B based on the first column selection signal CSL0.

In some embodiments, each of the first through fourth bit-line connectors 651, 653, 751 and 753, the first through fourth precharge circuits 652, 654, 752 and 754 and the first through fourth column gating circuits 655, 656, 755 and 756 may include one NMOS transistor.

In some embodiments, when the resistive-type memory device 600 of FIG. 15 performs a data-sensing operation, the first reference bit-lines RBL0 may operate as a complementary bit-line to the first bit-line BL0, and the second reference bit-lines RBL1 may operate as a complementary bit-line to the second bit-line BL1. The second local I/O line LIOL0B may also operate as a complementary local I/O line to the first local I/O line LIOL0, and the fourth local I/O line LIOL1B may operate as a complementary local I/O line to the third local I/O line LIOL1.

FIG. 16 depicts an arrangement of a resistive-type memory device according to exemplary embodiments.

Referring to FIG. 16, a resistive-type memory device 800 may include a plurality of banks 801-804 in which a plurality of memory cells are arranged in columns and rows. Each of the plurality of banks 801-804 may include a plurality of word-lines, a plurality of bit-lines, and a plurality of resistive-type memory cells that are disposed near intersections between the word-lines and the bit-lines.

The first bank 801 of the banks 801-804 may include a first bank array 810, a row decoder (R/D) 860a, a sense amplifier (S/A) 885a and a column decoder (C/D) 870a. The second bank 802 may include a second bank array 820, a row decoder 860b, a sense amplifier 885b and a column decoder 870b. The third bank 803 may include a third bank array 830, a row decoder 860c, a sense amplifier 885c and a column decoder 870c. The fourth bank 804 may include a third bank array 840, a row decoder 860d, a sense amplifier 885d and a column decoder 870d. The row decoder 860a may receive the bank address BANK_ADDR and the row address RA. The column decoder 870a may receive the column address (not shown). One bank of the plurality of banks 801-804 may be selected in response to the bank address BANK_ADDR, and memory cells in the selected bank may be accessed in response to the row address RA and the column address.

The first bank array 810 may include a first resistive-type memory cells RMC11, the second bank array 820 may include a second resistive-type memory cells RMC21, the third bank array 830 may include a third resistive-type memory cells RMC31, and the fourth bank array 840 may include a fourth resistive-type memory cells RMC41.

In some embodiments, each of the first resistive-type memory cells RMC11 may have a first feature size. Each of the second resistive-type memory cells RMC12 may have a second feature size that is greater than the first feature size. Each of the third resistive-type memory cells RMC13 may have a third feature size that is greater than the second feature size. Each of the fourth resistive-type memory cells RMC14 may have a fourth feature size that is greater than the third feature size.

In some embodiments, each of the first resistive-type memory cells RMC11 and each of the second resistive-type memory cells RMC12 may have a first feature size, and each of the third resistive-type memory cells RMC13 and each of the fourth resistive-type memory cells RMC14 may have a second feature size that is greater than the first feature size. Each of the first resistive-type memory cells RMC11 and each of the second resistive-type memory cells RMC12 may include the first STT-MRAM cell 30 of FIG. 6A, and each of the third resistive-type memory cells RMC13 and each of the fourth resistive-type memory cells RMC14 may include the first STT-MRAM cell 30′ of FIG. 6B. The first bank array 810 and the second bank array 820 may store data that requires rapid access, and the third bank array 830 and the fourth bank array 840 may store data requiring high reliability. Therefore, the resistive-type memory device 800 may provide data having both a rapid access time and a high reliability. Additionally, each of the first through fourth bank arrays 810, 820, 830 and 840 may include a plurality of reference resistive-type memory cells that provide a reference current that is used for sensing data in which each of the reference resistive-type memory cells may have the second feature size.

When an area that is occupied by the first bank array 810 is substantially the same as an area that is occupied by the third bank array 830, a first number of the first resistive-type memory cells coupled to a word-line in the first bank array 810 may be greater than a second number of the second resistive-type memory cells coupled to a word-line in the third bank array 830.

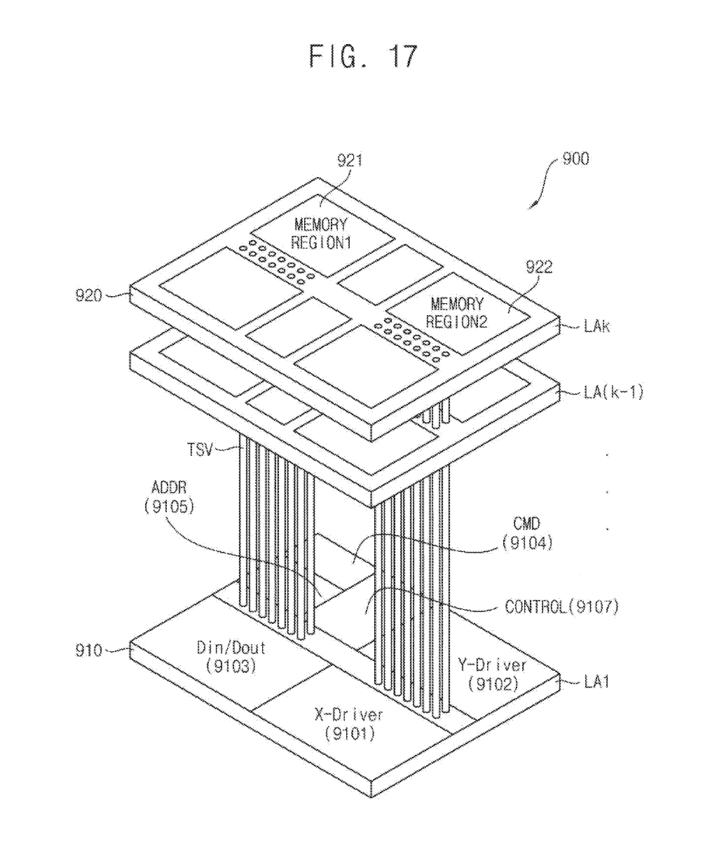

FIG. 17 is a structural diagram depicting a resistive-type memory device according to exemplary embodiments.

Referring to FIG. 17, a resistive-type memory device 900 may include first through k-th semiconductor integrated circuit layers LA1 through LAk (in which k is a natural number greater than two). The lowest first semiconductor integrated circuit layer LA1 is an interface or a control chip, and the other semiconductor integrated circuit layers LA2 through LAk are slave chips that include core memory chips. The first through k-th semiconductor integrated circuit layers LA1 through LAk may transmit and receive signals between the layers through through-silicon vias (TSVs). The first semiconductor integrated circuit layer LA1 as the interface or control chip may communicate with an external memory controller through a conductive structure formed on an external surface. A description regarding structure and an operation of the resistive-type memory device 900 will be provided by mainly focusing on the first semiconductor integrated circuit layer LA1 (or 910) as the interface or control chip and the n-th semiconductor integrated circuit layer LAk (or 920) as the slave chip.

The first semiconductor integrated circuit layer 910 may include various peripheral circuits for driving a first memory region 921 and a second memory region 922 provided in the k-th semiconductor integrated circuit layer 920. For example, the first semiconductor integrated circuit layer 910 may include a row X-driver 9101 for driving word-lines of a memory, a column Y-driver 9102 for driving bit-lines of the memory, a data input/output unit (Din/Dout) 9103 for controlling input/output of data, a command buffer (CMD) 9104 for receiving a command CMD from outside and buffering the command CMD, and an address buffer (ADDR) 9105 for receiving an address from outside and buffering the address. As described in connection with FIGS. 4A through 11B, the first memory region 921 may include a plurality of first resistive-type memory cells, each having a first feature size, and the memory region 922 may include a plurality of second resistive-type memory cells, each having a second feature size that is greater than the first feature size. The first memory region 921 may store data requiring rapid access, and the second memory region 922 may store data requiring high reliability. Therefore, the resistive-type memory device 900 may provide both data having a high reliability and a low power consumption.

The first semiconductor integrated circuit layer 910 may further include a control logic 9107. The control logic 9107 may control an access to the first memory region 921 and the second memory region 922 based on a command and an address signal received from an external memory controller, and may generate control signals for accessing the first memory region 921 and the second memory region 922.

The k-th semiconductor integrated circuit layer 920 may include a peripheral circuit region that may include peripheral circuits for reading/writing data of the first memory region 921 and the second memory region 922.

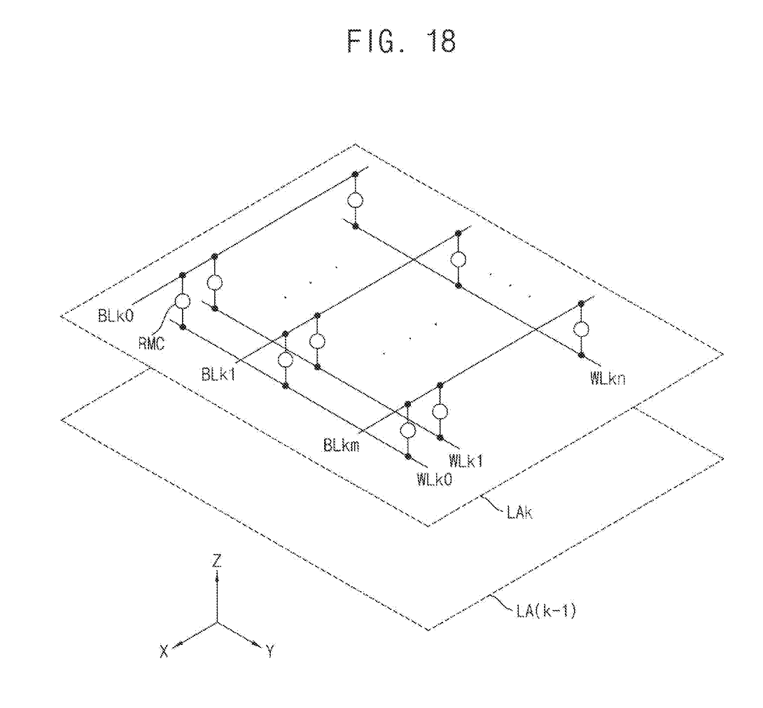

FIG. 18 depicts a configuration of the semiconductor integrated circuit layers in FIG. 17.

In FIG. 18, the k-th semiconductor integrated circuit layer LAk is depicted in detail in which each configuration of other semiconductor integrated circuit layers LA2-LA(k−1) is similar to the configuration of the k-th semiconductor integrated circuit layer LAk.

Referring to FIG. 18 the k-th semiconductor integrated circuit layer LAk may include a plurality of (e.g., m+1) bit-lines BLk0 to BLkm disposed lengthwise in the X axis direction with a predetermined space therebetween, and a plurality of (e.g., n+1) word-lines WLk0 to WLkn disposed lengthwise in the Y axis direction with a predetermined space therebetween. A resistive-type memory cell RMC may be disposed at each of intersection points of the word-lines WLk0 to WLkn and the bit-lines BLk0 to BLkm. The resistive-type memory cell RMC may include a STT-MRAM cell as described in connection with FIGS. 6 through 11B. Additionally, although not depicted, a sense amplifier circuit may be disposed in peripheral circuit regions in the k-th semiconductor integrated circuit layer LAk as described in connection with FIGS. 6A through 11B.

In exemplary embodiments, a plurality of resistive-type memory cells that have different feature sizes may be arranged in each of the semiconductor integrated circuit layers LA2-LAk. Therefore, the resistive-type memory device 900 may select one or more of the semiconductor integrated circuit layers LA2-LAk in which data is to be stored, depending on data characteristic.

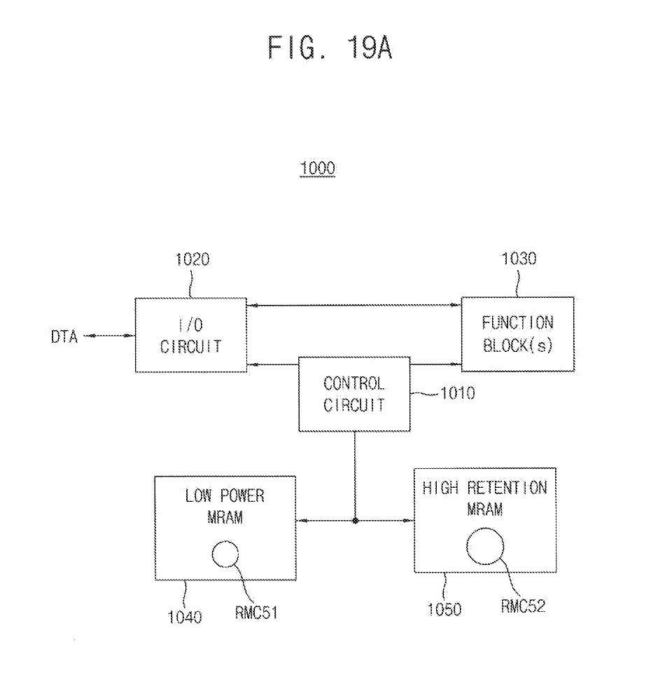

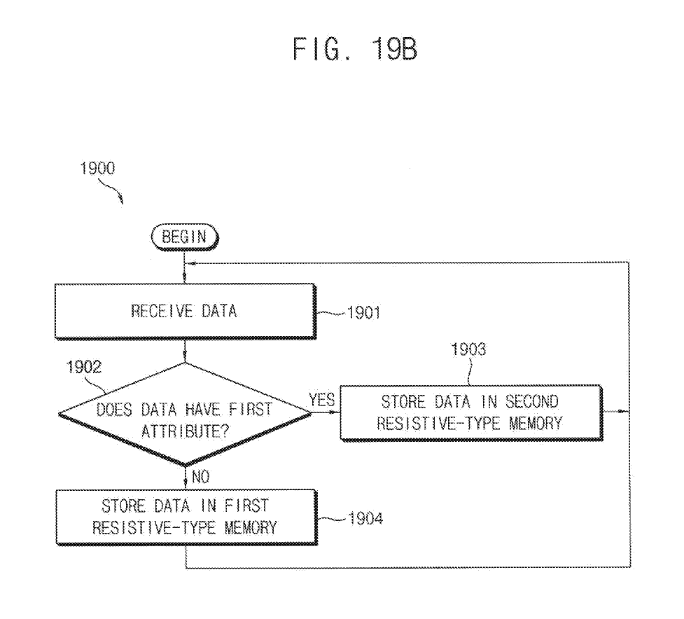

FIG. 19A is a block diagram depicting an integrated circuit (IC) including the resistive-type memory device according to exemplary embodiments. FIG. 19B is a flow diagram of an exemplary embodiment of a method 1900 for storing data according to exemplary embodiments.

Referring to FIG. 19A, an integrated circuit (IC) 1000 may include a control circuit 1010, an I/O circuit 1020, a function block(s) 1030, a first resistive-type memory 1040 and a second resistive type memory 1050.

As indicated at operation 1901 in FIG. 19B, the I/O circuit 1020 may receive input data DTA from an external device and may provide output data DTA to the external device. The function block(s) 1030 may perform a particular function. The first resistive-type memory 1040 may include a plurality of first resistive memory cells RMC51, each having a first feature size and the second resistive-type memory 1050 may include a plurality of second resistive memory cells RMC52, each having a second feature size that is greater than the first feature size. The control circuit 1010 may control the I/O circuit 1020 to store the input data DTA in one of the first resistive-type memory 1040 and the second resistive-type memory IP 1050.

If, as indicated at 1902 in FIG. 19B, an attribute of the input data DTA indicates that the data DTA has a first attribute that corresponds to a high data-retention characteristic, flow continues to operation 1903 where the control circuit 1010 controls the I/O circuit 1020 to store the input data DTA in the second resistive-type memory 1050. If the attribute of the received input data DTA does not have a high data-retention characteristic, the data DTA has a second attribute that corresponds to a low data-retention characteristic and a rapid access time and flow continues to operation 1904 where the control circuit 1010 controls the I/O circuit 1020 to store the input data DTA in the first resistive-type memory 1040. That is, if an attribute of the input data DTA indicates that the data DTA has a second attribute that corresponds to a low data-retention characteristic and rapid access time, flow continues to operation 1904 wherein the control circuit 1010 controls the I/O circuit 1020 to store the input data DTA in the first resistive-type memory 1040. The IC 1000 may provide both a low power characteristic and a high reliability characteristic by selectively storing data in the first resistive-type memory 1040 or the second resistive-type memory 1050 depending on attribute of the data DTA.

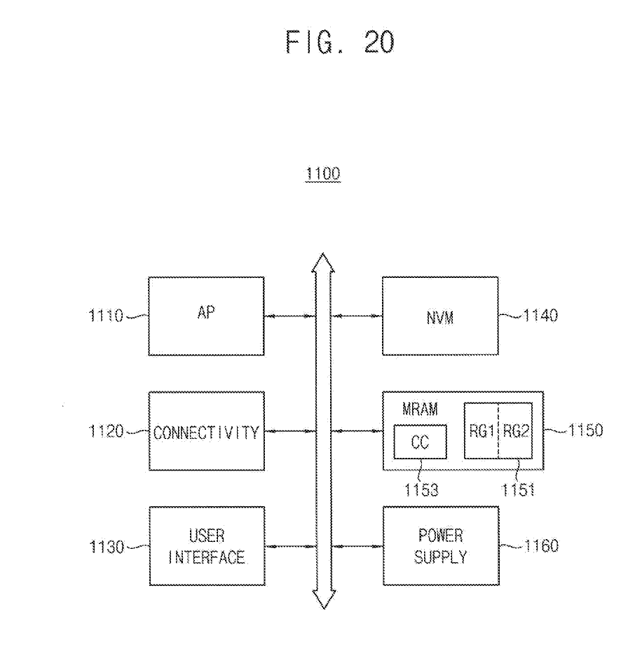

FIG. 20 is a block diagram depicting a mobile system that includes the resistive-type memory device according to exemplary embodiments.

Referring to FIG. 20, a mobile system 1100 may include an application processor (AP) 1110, a connectivity unit 1120, a resistive-type memory device 1150, a nonvolatile memory device 1140, a user interface 1130, and a power supply 1160.

The application processor 1110 may execute applications, such as a web browser, a game application, a video player, etc. The connectivity unit 1120 may perform wired or wireless communication with an external device.

The resistive-type memory device 1150 may store data processed by the application processor 1110 or operate as a working memory. The resistive-type memory device 1150 may include a memory cell array 1151 and a control circuit 1153 that controls access on the memory cell array 1151. The memory cell array 1151 may include a first memory region RG1 in which first resistive-type memory cells are arranged and a second memory region RG2 in which second resistive-type memory cells are arranged. Each of the first resistive-type memory cells may have a first feature size and each of the second resistive-type memory cells may have a second feature size that is greater than the first feature size.

The nonvolatile memory device 1140 may store a boot image for booting the mobile device 1100. The user interface 1130 may include at least one input device, such as a keypad, a touch screen, etc., and at least one output device, such as a speaker, a display device, etc. The power supply 1160 may supply a power supply voltage to the mobile system 1100.

In some embodiments, the mobile system 1100 and/or components of the mobile device 1100 may be packaged in various forms.

The present disclosure may be applied to systems using a system using a resistive-type memory device. The present disclosure may be applied to systems such as be a mobile phone, a smart phone, a personal digital assistant (PDA), a portable multimedia player (PMP), a digital camera, a camcorder, personal computer (PC), a server computer, a workstation, a laptop computer, a digital TV, a set-top box, a portable game console, a navigation system, etc.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present disclosure. Accordingly, all such modifications are intended to be included within the scope of the present disclosure as defined in the claims.

What is claimed is:

1. A resistive-type memory device, comprising:
a memory cell array; and
a control logic circuit configured to access the memory cell array in response to a received command and a received address,
wherein the memory cell array includes at least a first group of resistive-type memory cells and a second group of resistive-type memory cells, and
each of the first group of resistive-type memory cells has a first feature size and each of the second group of resistive-type memory cells has a second feature size that is different from the first feature size.

2. The resistive-type memory device of claim 1, wherein the first feature size is smaller than the second feature size.

3. The resistive-type memory device of claim 2, wherein a first data-retention characteristic of each of the first group of resistive-type memory cells is less than a second data-retention characteristic of each of the second group of resistive-type memory cells.

4. The resistive-type memory device of claim 1, wherein a first resistive-type memory cell of the first group of resistive-type memory cells comprises:
a first magnetic tunnel junction (MTJ) element that has a first terminal coupled to a bit-line, the first MTJ element having a cylindrical shape; and
a cell transistor that has a first electrode coupled to a second terminal of the first MJT element, a gate terminal coupled to a word-line and a second electrode coupled to a source line,
wherein a second resistive-type memory cell of the second group of resistive-type memory cells comprises:
a second MTJ element that has a first terminal coupled to a reference bit-line, the second MTJ element having a cylindrical shape; and
a reference cell transistor that has a first electrode coupled to a second terminal of the second MJT element, a gate terminal coupled to the word-line and a second electrode coupled to the source line, and
wherein a first diameter of the first MTJ element is less than a second diameter of the second MTJ element.

5. The resistive-type memory device of claim 4, further comprising a bit-line sense amplifier coupled between the bit-line and the reference bit-line,
wherein the bit-line sense amplifier is configured to sense data stored in the first resistive-type memory cell based on a reference current of the reference bit-line.

6. The resistive-type memory device of claim 1, wherein the memory cell array comprises a plurality of bank arrays, each of the plurality of bank arrays being identified by a bank address of the received address,
wherein a first bank array of the plurality of bank arrays includes the first group of resistive-type memory cells,
wherein a second bank array of the plurality of bank arrays includes the second group of resistive-type memory cells, and
wherein the first feature size is smaller than the second feature size.

7. The resistive-type memory device of claim 6, wherein a first number of first resistive-type memory cells coupled to a first word-line of the first bank array is greater than a second number of second resistive-type memory cells coupled to a first word-line of the second bank array.

8. The resistive-type memory device of claim 1, wherein the memory cell array comprises a plurality of bank arrays, each of the plurality of bank arrays being identified by a bank address of the received address,
wherein each of the plurality of bank arrays includes a first memory region and a second memory region that are identified by a portion of the received address,
wherein the first memory region includes the first group of resistive-type memory cells,
wherein the second memory region includes the second group of resistive-type memory cells, and
wherein the first feature size is less than the second feature size.

9. The resistive-type memory device of claim 8, wherein a first number of first resistive-type memory cells in the first memory region, coupled to one word-line is greater than a second number of second resistive-type memory cells in the second memory region, coupled to the one word-line.

10. The resistive-type memory device of claim 1, wherein the memory cell array comprises a plurality of bank arrays, each of the plurality of bank arrays being identified by a bank address of the address,
wherein each of the plurality of bank arrays includes a plurality of sub array blocks and a plurality of bit-line sense amplifier regions disposed adjacent to the plurality of sub array blocks, and
wherein the first group of resistive-type memory cells and the second group of resistive-type memory cells are respectively disposed in two different sub array blocks adjacent to the bit-line sense amplifier, of the plurality of sub array blocks.

11. The resistive-type memory device of claim 1, wherein the memory cell array includes at least a first semiconductor layer and a second semiconductor layer that are stacked vertically with respect to a substrate,
wherein the first semiconductor layer includes the first group of resistive-type memory cells,
wherein the second semiconductor layer includes the second group of resistive-type memory cells, and
wherein the first feature size is less than the second feature size.

12. The resistive-type memory device of claim 1, wherein each of the first group of resistive-type memory cells and each of the second group of resistive-type memory cells are a spin transfer torque magneto-resistive random access memory (STT-MRAM) cell that includes a magnetic tunnel junction (MTJ) element and a cell transistor.

13. The resistive-type memory device of claim 1, wherein the resistive-type memory device is a magnetic random access memory (MRAM), a resistive random access memory (RRAM), a phase-change random access memory (PRAM), or a ferroelectric random access memory (FRAM).

14. An integrated circuit (IC), comprising:
an input/output circuit configured to receive input data and configured to provide output data;
a first resistive-type memory intellectual property (IP) including a plurality of first resistive-type memory cells;
a second resistive-type memory IP including a plurality of second resistive-type memory cells; and
a control circuit configured to control the input/output circuit to store the input data in at least a portion of the first resistive-type memory IP and the second resistive-type memory IP,
wherein each of the first resistive-type memory cells has a first feature size and each of the second resistive-type memory cells has a second feature size that is different from the first feature size, and
wherein the first feature size is less than the second feature size.

15. The IC of claim 14, wherein the control circuit is configured to:
store the input data in the second resistive-type memory IP if an attribute of the input data requires a first data-retention characteristic; or
store the input data in the first resistive-type memory IP if the attribute of the input data requires a second data-retention characteristic that is less than the first data-retention characteristic.

16. A memory device, comprising:
a first group of resistive-type memory cells, each memory cell of the first group of resistive-type memory cells comprising a first feature size;
a second group of resistive-type memory cells, each memory cell of the second group of resistive-type memory cells comprising a second feature size that is different than the first feature size; and
a controller coupled to the first group of resistive-type memory cells and the second group of resistive-type memory cells, the controller configured to determine if an attribute of data received to be stored in the memory device indicates that the received data is to be stored in the first group of resistive-type memory cells or the second group of resistive-type memory cells.

17. The memory device of claim 16, wherein a first number of memory cells of the first group of resistive-type memory cells are coupled to a first word-line, and a second number of memory cells of the second group of resistive-type memory cells are coupled to the first word-line, the first number being greater than the second number.

18. The memory device of claim 16, wherein the second feature size is greater than the first feature size.

19. The memory device of claim 18, wherein the first feature size comprises a diameter of a memory cell in the first group of resistive-type memory cells, and the second feature size comprises a diameter of a memory cell in the second group of resistive-type memory cells.

20. The memory device of claim 18, wherein the attribute indicates whether the received data has a high data-retention characteristic or a low data-retention characteristic,
wherein if the attribute indicates that the received data has a high data-retention characteristic, the controller is to store the received data in the second group of resistive-type memory cells, and
wherein if the attribute indicates that the received data has a low data-retention characteristic, the controller is to store the received data in the first group of resistive-type memory cells.
